(19) United States
(12) Patent Application Publication
(10) Pub. No.: US 2026/0353983 A1
(43) Pub. Date: Nov. 5, 2026

(54) PROTECTIVE LAYER COMPOSITION, PROTECTIVE LAYER, AND DISPLAY DEVICE

(71) Applicant: Duk San Neolux Co., Ltd., Cheonan-si (KR)

(72) Inventors: Kyung Soo KIM, Cheonan-si (KR); Hyo Jung SON, Cheonan-si (KR); Yeon Soo LEE, Cheonan-si (KR); Jun BAE, Cheonan-si (KR); Ju Cheol KWON, Cheonan-si (KR); Do Eon KIM, Cheonan-si (KR)

(21) Appl. No.: 19/650,411

(22) Filed: Apr. 17, 2026

(30) Foreign Application Priority Data
Apr. 18, 2025 (KR) 10-2025-0051132
Mar. 31, 2026 (KR) 10-2026-0057886

(51) Int. Cl. H10K 59/80; C09D 4/00; C09D 7/61; C09D 7/63; C09D 133/08; H10K 102/00

(52) U.S. Cl. CPC H10K 59/873; C09D 4/00; C09D 7/61; C09D 7/63; C09D 133/08; H10K 2102/311

(57) ABSTRACT

Embodiments of the present disclosure may provide a composition comprising a monomer comprising an acrylate group, an adhesion promoter comprising silicon, and a colorant. Accordingly, the embodiments of the present disclosure may provide a protective layer composition, a protective layer comprising the same, and a display device, which can improve adhesion between a display panel and a protective layer, enhance durability and reliability, improve antistatic capability, and preserve optical characteristics of a display while being robust against heat and moisture and having flexibility.

### CROSS-REFERENCE TO RELATED APPLICATIONS

This application claims under 35 U.S.C. § 119(a) the benefit of priority to Republic of Korea Patent Application No. 10-2025-0051132, filed on Apr. 18, 2025, and Republic of Korea Patent Application No. 10-2026-0057886, filed on Mar. 31, 2026, which are hereby incorporated by reference for all purposes as if fully set forth herein.

### TECHNICAL FIELD

Embodiments of the present disclosure relate to a protective layer composition, a protective layer, and a display device.

### RELATED ART

A display panel may need to be protected from external impact, scratches, abrasion, and the like, and for this purpose, a protective layer may be disposed under the display panel. The protective layer may play an important role in protecting the display panel and improving performance.

Various studies on protective layer compositions are being conducted to satisfy requirements such as high adhesion to a display panel, appropriate flexibility, optical transparency, and heat resistance.

### SUMMARY

Embodiments of the present disclosure may provide a protective layer composition that improves adhesion between a display panel and a protective layer.

Embodiments of the present disclosure may provide a protective layer composition and a protective layer that improve durability and reliability and prevent degradation of display panel performance by enhancing antistatic capability.

Embodiments of the present disclosure may provide a protective layer composition and a protective layer that have high resistance to heat and moisture to suppress deterioration of an OLED display and have high flexibility and impact resistance to be applicable to a flexible display.

Embodiments of the present disclosure may provide a protective layer comprising a protective layer composition and a display device comprising the same.

The problems to be solved by the embodiments of the present disclosure are not limited to the problems mentioned in the present disclosure, and other problems not mentioned will be clearly understood by those skilled in the art from the following description.

A protective layer composition according to embodiments of the present disclosure may comprise a colorant, a monomer comprising an acrylate group, and an adhesion promoter comprising silicon (Si).

The monomer may be a compound represented by Formula 1 below, and the adhesion promoter comprising Si may be a compound represented by Formula 2 below.

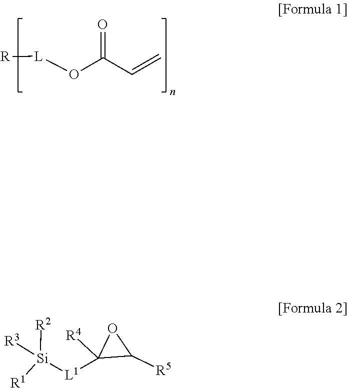

A protective layer according to embodiments of the present disclosure may comprise a protective layer composition.

A display device according to embodiments of the present disclosure may comprise a display panel comprising a pixel array layer, and a protective layer positioned under the display panel.

According to embodiments of the present disclosure, a protective layer composition and a protective layer that improve adhesion between the protective layer and a display panel may be provided.

According to embodiments of the present disclosure, a protective layer composition and a protective layer that improve durability and reliability and enhance antistatic capability to prevent performance degradation of a display panel may be provided.

According to embodiments of the present disclosure, a protective layer composition and a protective layer that have high resistance to heat and moisture to suppress deterioration of an OLED display and have high flexibility and impact resistance to be applicable to a flexible display may be provided.

According to embodiments of the present disclosure, a display device capable of low-power driving by improving performance and lifespan of the display device may be provided.

Effects of the embodiments of the present disclosure are not limited to the effects mentioned above, and other effects not mentioned will be clearly understood by those skilled in the art from the description below.

### BRIEF DESCRIPTION OF THE DRAWINGS

The contents of the present disclosure will be more completely understood from the detailed description provided below and the accompanying drawings, which are provided for explanation only and do not limit the contents of the present disclosure.

FIG. 1 is an exemplary cross-sectional view schematically illustrating a display device according to embodiments of the present disclosure.

FIG. 2 is an exemplary cross-sectional view illustrating an enlarged cross-section of region A shown in FIG. 1.

FIGS. 3A and 3B are exemplary views illustrating optical paths in a display device according to embodiments of the present disclosure and a display device according to a comparative example.

FIGS. 4A to 4D are exemplary process diagrams schematically illustrating manufacturing steps of a display device according to embodiments of the present disclosure.

### DETAILED DESCRIPTION

Hereinafter, embodiments of the present disclosure will be described in detail with reference to the illustrative drawings.

In the following description of the present disclosure, a detailed description of known functions and configurations incorporated herein will be omitted in the case in which the subject matter of the present disclosure may be rendered unclear thereby. It will be understood that the terms “comprise”, “have”, “consist of”, and any variations thereof used herein are intended to cover non-exclusive inclusions unless explicitly stated to the contrary. Descriptions of elements in the singular form used herein are intended to include descriptions of elements in the plural form, unless explicitly stated to the contrary.

In addition, terms, such as first, second, A, B, (a), or (b), may be used herein when describing elements of the present disclosure. Each of these terminologies is not used to define an essence, order, or sequence of a corresponding element but used merely to distinguish the corresponding element from other elements.

It will be understood that when an element is referred to as being “connected”, “coupled”, or “joined” to another element, not only can it be “directly connected, coupled, or joined” to the other element, but it can also be “indirectly connected, coupled, or joined” to the other element via an “intervening” element. Here, the intervening element may be included in one or more of the two elements “connected”, “coupled”, or “joined” to each other.

In addition, it will be understood that when an element, such as a layer, a film, or a region, or a plate, is referred to as being “above” or “on” another element, not only can it be “directly” above or on the other element, but it can also be “indirectly” above or on the other element or layer via an “intervening” element. In contrast, when an element is referred to as being “directly” above or on another element, it will be understood that no intervening element is interposed.

When time relative terms, such as “after”, “subsequent to”, “next”, “before”, and the like, are used to describe elements, operating or manufacturing methods, and the like, these terms may be used to describe non-consecutive or non-sequential processes or operations unless the term “directly” or “immediately” is used together.

In addition, when any numerical values for elements or corresponding information are mentioned, it should be considered that numerical values for elements or corresponding information include a tolerance or error range that may be caused by various factors (e.g., process factors, internal or external impact, noise, etc.) even when a relevant description is not specified.

The terms used in the present disclosure and the appended claims are as follows, unless otherwise stated, within the scope not departing from the spirit of the present disclosure.

The terms “halo” or “halogen” as used in the present disclosure comprise fluorine (F), chlorine (Cl), bromine (Br), and iodine (I), unless otherwise specified.

The terms “alkyl” or “alkyl group” as used in the present disclosure, unless otherwise specified, refer to a radical of a saturated aliphatic functional group having 1 to 60 carbons connected by a single bond, comprising a straight-chain alkyl group, a branched-chain alkyl group, a cycloalkyl (alicyclic) group, an alkyl-substituted cycloalkyl group, and a cycloalkyl-substituted alkyl group.

The terms “haloalkyl group” or “halogenalkyl group” as used in the present disclosure, unless otherwise specified, refer to an alkyl group substituted with a halogen.

The terms “alkenyl” or “alkynyl” as used in the present disclosure, unless otherwise specified, each have a double bond or a triple bond, comprise a straight-chain or branched-chain group, and may have 2 to 60 carbon atoms, but are not limited thereto.

The term “cycloalkyl” as used in the present disclosure, unless otherwise specified, refers to an alkyl forming a ring having 3 to 60 carbon atoms, but is not limited thereto.

The terms “alkoxy group” or “alkyloxy group” as used in the present disclosure refer to an alkyl group bonded to an oxygen radical, and unless otherwise specified, have 1 to 60 carbon atoms, but are not limited thereto.

The terms “alkenoxyl group,” “alkenoxy group,” “alkenyloxyl group,” or “alkenyloxy group” as used in the present disclosure refer to an alkenyl group attached to an oxygen radical, and unless otherwise specified, have 2 to 60 carbon atoms, but are not limited thereto.

The terms “aryl group” and “arylene group” as used herein each comprise 6 to 60 carbon atoms, unless otherwise specified, but are not limited thereto. In the present disclosure, an aryl group or an arylene group comprises a monocyclic type, a ring assembly, a fused polycyclic compound, and the like. For example, an aryl group may comprise a phenyl group, a monovalent functional group of biphenyl, a monovalent functional group of naphthalene, a fluorenyl group, and a substituted fluorenyl group, and an arylene group may comprise a fluorenylene group and a substituted fluorenylene group.

The term “ring assemblies” as used herein refers to a structure in which two or more ring systems (monocyclic or fused ring systems) are directly connected to each other via a single bond or a double bond, and the number of such direct connections between the rings is one less than the total number of ring systems present in the compound. A ring assembly may comprise identical or different ring systems directly connected to each other via a single bond or a double bond.

In the present disclosure, since an aryl group comprises a ring assembly, the aryl group comprises biphenyl and terphenyl, in which a benzene ring, which is a single aromatic ring, is connected by a single bond. Further, the aryl group also comprises a compound in which an aromatic monocyclic ring and a fused aromatic ring system are connected by a single bond. For example, the aryl group also comprises a compound in which fluorene, which is a fused aromatic ring system, and a benzene ring, which is an aromatic monocyclic ring, are connected by a single bond.

The term “fused polycyclic system” as used herein refers to a fused ring form sharing at least two atoms, and comprises a form in which two or more hydrocarbon ring systems are fused and a form in which at least one heterocyclic system comprising at least one heteroatom is fused. Such a fused polycyclic system may be an aromatic ring, a heteroaromatic ring, an aliphatic ring, or a combination of these rings. For example, in the case of an aryl group, it may be a naphthalenyl group, a phenanthrenyl group, a fluorenyl group, or the like, but is not limited thereto.

The term “spiro compound” as used herein comprises a ‘spiro union’, wherein a spiro union refers to a connection formed by two rings sharing only one atom. In this case, the atom shared by the two rings is referred to as a ‘spiro atom’, and depending on the number of spiro atoms present in a compound, these are referred to as ‘monospiro-’, ‘dispiro-’, and ‘trispiro-’ compounds, respectively.

The terms “fluorenyl group”, “fluorenylene group”, and “fluorenyltriyl group” as used herein each refer to a monovalent, divalent, or trivalent functional group in which R¹, R², R³, and R⁴ are all hydrogen in the following structure, unless otherwise specified. A “substituted fluorenyl group”, a “substituted fluorenylene group”, or a “substituted fluorenyltriyl group” refers to a case where at least one of the substituents R¹, R², R³, and R⁴ is a substituent other than hydrogen, and also comprises a case where R¹ and R² are bonded to each other to form a spiro compound together with the carbon atom to which they are bonded. In the present disclosure, the fluorenyl group, the fluorenylene group, and the fluorenyltriyl group may all be referred to as a fluorene group, regardless of their valency, such as monovalent, divalent, or trivalent.

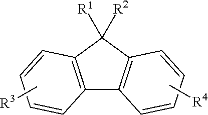

Further, R¹, R², R³, and R⁴ may each independently be an alkyl group comprising 1 to 20 carbon atoms, an alkenyl group comprising 1 to 20 carbon atoms, an aryl group comprising 6 to 30 carbon atoms, or a heterocyclic group comprising 2 to 30 carbon atoms. For example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or a divalent functional group of 9,9-dimethylfluorene, 9,9-diphenylfluorene, and 9,9′-spirobi[9H-fluorene].

The term “heterocyclic group” as used herein comprises not only aromatic rings such as a “heteroaryl group” or a “heteroarylene group” but also non-aromatic rings, and unless otherwise specified, each refers to a ring comprising 2 to 60 carbon atoms and at least one heteroatom, but is not limited thereto. The term “heteroatom” as used herein represents oxygen (O), nitrogen (N), sulfur(S), silicon (Si), or phosphorus (P), unless otherwise specified, and a heterocyclic group refers to a monocyclic type, a ring assembly, a fused polycyclic system, a spiro compound, and the like, comprising a heteroatom.

For example, a “heterocyclic group” may also comprise a compound comprising a heteroatomic group such as SO₂, P═O, or the like, instead of a carbon atom forming a ring, as in the following compound.

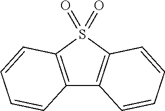 [SMILES: O=S1(=O)c2ccccc2-c2ccccc21]

The term “ring” as used herein comprises a monocyclic ring and a polycyclic ring, and comprises a hydrocarbon ring as well as a heterocyclic ring comprising at least one heteroatom, and comprises an aromatic ring and a non-aromatic ring.

The term “polycyclic ring” as used herein comprises ring assemblies such as biphenyl, terphenyl, and the like, fused polycyclic systems, and spiro compounds, and comprises not only aromatic but also non-aromatic rings, and comprises a hydrocarbon ring as well as a heterocyclic ring comprising at least one heteroatom.

The term “aliphatic ring group” as used herein refers to a cyclic hydrocarbon excluding an aromatic hydrocarbon, and comprises a monocyclic type, a ring assembly, a fused polycyclic system, a spiro compound, and the like, and unless otherwise specified, refers to a ring comprising 3 to 60 carbon atoms, but is not limited thereto. For example, even in a case where benzene, which is an aromatic ring, and cyclohexane, which is a non-aromatic ring, are fused, it corresponds to an aliphatic ring.

Further, when prefixes are named consecutively, it means that substituents are listed in the order in which they are first described. For example, an arylalkoxy group refers to an alkoxy group substituted with an aryl group, an alkoxycarbonyl group refers to a carbonyl group substituted with an alkoxy group, and an arylcarbonylalkenyl group refers to an alkenyl group substituted with an arylcarbonyl group, wherein the arylcarbonyl group is a carbonyl group substituted with an aryl group.

In the term “substituted or unsubstituted” as used in the present disclosure, “substituted” means being substituted with one or more substituents selected from the group consisting of deuterium, a halogen group, a hydroxy group (—OH), a nitrile group (—CN), a nitro group (—NO₂), a carbonyl group (—C(═O)—), an ether group (—O—), an ester group (—C(═O)O—), a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P, but is not limited to these substituents.

In the present disclosure, a ‘functional group name’ corresponding to an aryl group, an arylene group, a heterocyclic group, and the like, exemplified by each symbol and its substituent, may be described as ‘a functional group name reflecting valency’ or may be described as ‘a parent compound name’. For example, in the case of ‘phenanthrene’, which is a type of aryl group, a monovalent ‘group’ may be referred to as ‘phenanthryl (group)’, and a divalent group may be referred to as ‘phenanthrylene (group)’ or the like, distinguishing the valency of the group, but it may also be referred to as ‘phenanthrene (group)’, which is the parent compound name, regardless of the valency.

Similarly, in the case of pyrimidine, it may be described as ‘pyrimidine’ regardless of valency, or as pyrimidinyl (group) in the case of a monovalent group, or as pyrimidinylene (group) or the like, as the ‘name of the group’ corresponding to its valency, in the case of a divalent group. Therefore, when the type of a substituent is described by a parent compound name in the present disclosure, it may refer to an n-valent ‘group’ formed by the detachment of a hydrogen atom bonded to a carbon atom and/or a heteroatom of the parent compound.

Further, in the present disclosure, in describing a compound name or a substituent name, numbers or alphabets indicating positions may be omitted. For example, pyrido[4,3-d]pyrimidine may be described as pyridopyrimidine, benzofuro[2,3-d]pyrimidine as benzofuropyrimidine, and 9,9-dimethyl-9H-fluorene as dimethylfluorene, and the like. Accordingly, both benzo[g]quinoxaline and benzo[f]quinoxaline may be described as benzoquinoxaline.

Further, unless explicitly stated otherwise, a chemical formula used in the present disclosure is applied identically to a substituent definition by an index definition of the following chemical formula.

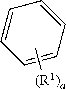

Herein, when ‘a’ is an integer of 0, it means that a substituent R¹ is absent, that is, when ‘a’ is 0, it means that all carbon atoms forming a benzene ring are bonded to hydrogen atoms, and in this case, the indication of hydrogen atoms bonded to the carbon atoms may be omitted when describing a chemical formula or a compound. Further, when ‘a’ is an integer of 1, one substituent R¹ is bonded to any one of the carbon atoms forming the benzene ring, and when ‘a’ is an integer of 2 or 3, it may be bonded, for example, as shown below, and when ‘a’ is an integer of 4 to 6, it is bonded to the carbon atoms of the benzene ring in a similar manner, and when ‘a’ is an integer of 2 or more, the R¹ groups may be the same or different from each other.

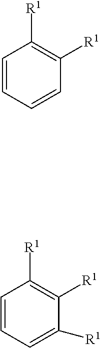

Unless otherwise specified in the present disclosure, forming a ring means that adjacent groups are bonded to each other to form a single ring or multiple fused rings, and the single ring and the formed multiple fused rings comprise a hydrocarbon ring as well as a heterocyclic ring comprising at least one heteroatom, and may comprise an aromatic ring and a non-aromatic ring.

Further, unless otherwise specified in the present disclosure, when indicating a fused ring, the number in ‘N-fused ring’ indicates the number of rings being fused. For example, a form in which three rings are fused to each other, such as anthracene, phenanthrene, or benzoquinazoline, may be denoted as a 3-fused ring.

Meanwhile, the term “bridged bicyclic compound” as used in the present disclosure, unless otherwise specified, refers to a compound in which two rings share three or more atoms to form a ring. In this case, the shared atoms may comprise a carbon atom or a heteroatom.

In the present disclosure, a display device may be implemented in various forms, and specifically, may comprise an organic light-emitting diode (OLED) display, a liquid crystal display (LCD), an electronic ink display, a micro-LED display, and a quantum dot (QD) display. Further, such a display device may be provided in various forms, such as a curved display, a flexible display, a foldable display, and a rollable display, in addition to a flat display. Furthermore, special purpose displays such as a small display for wearable devices, a head-up display (HUD) for vehicles, a head-mounted display (HMD) for augmented reality (AR) and virtual reality (VR), and a transparent display may also be included.

Further, the display device in the present disclosure may refer to a panel comprising the display devices described above, or may comprise a panel and a circuit. Herein, for example, it may comprise personal electronic devices such as a smartphone, a tablet, a laptop, and a desktop computer, and large display devices such as a television, a monitor, and digital signage may also be included. Further, vehicular display devices such as a head-up display (HUD) and an instrument panel display for automobiles, wearable devices (e.g., a smartwatch), head-mounted displays (HMDs) for virtual reality (VR) and augmented reality (AR) devices, and special purpose display devices such as medical monitors and industrial control panels may also be included.

Hereinafter, embodiments of the present disclosure will be described in detail. However, these are presented as examples, and the present disclosure is not limited thereby, but is defined only by the scope of the claims described later.

A display device should be protected from external impacts, scratches, abrasion, and the like, and for this purpose, a protective layer may be disposed below a display panel. The protective layer may play an important role in protecting the display panel and improving its performance.

A conventional protective layer had insufficient adhesion to a display panel, which caused problems with the durability and reliability of a product.

For example, in the case of a flexible display, there was a problem of shortened product lifespan due to insufficient adhesion of a conventional protective layer. As another example, a conventional protective layer had insufficient antistatic capability, which could lead to degradation of the performance of the display panel.

Maintaining optical characteristics of a display when applying a protective layer has also been an important challenge.

Accordingly, a new composition comprising a monomer comprising an acrylate group, an adhesion promoter comprising silicon (Si), and a colorant has been developed. This composition may be applied to various display products because it improves adhesion to a display panel, provides flexibility, and allows for adjustment of optical characteristics.

A protective layer composition according to embodiments of the present disclosure may be included in a protective layer.

Hereinafter, components of the protective layer composition will be described in detail.

A protective layer composition according to embodiments of the present disclosure may comprise a colorant, a monomer comprising an acrylate group, and an adhesion promoter comprising silicon.

The protective layer composition according to embodiments of the present disclosure may further comprise an initiator and a solvent.

The protective layer composition according to embodiments of the present disclosure may be included in a protective layer.

A protective layer comprising the protective layer composition according to embodiments of the present disclosure may be included in a display device.

A protective layer according to embodiments of the present disclosure may prevent degradation of display performance by improving durability and reliability of a display device through improved adhesion.

The protective layer composition may comprise the compositions to be described below.

### [Compositions Included in the Protective Layer Composition]

### 1. Colorant

In embodiments of the present disclosure, the protective layer composition may comprise a colorant. The colorant may comprise a black pigment.

For example, the black pigment may include lactam black, aniline black, perylene black, titanium black, carbon black, and the like, but is not limited thereto.

For example, the black pigment may be used together with a color correction agent such as an anthraquinone-based pigment, a perylene-based pigment, a phthalocyanine-based pigment, an azo-based pigment, or the like.

The colorant in the protective layer composition may further comprise a dye. For example, the dye may comprise a phthalocyanine-based compound.

The pigment and the dye may be used alone or in a mixture of two or more thereof, but are not limited thereto.

A dispersant may be used together to disperse the pigment in the protective layer composition. For example, the pigment may be pre-surface treated with the dispersant, or the dispersant may be added together with the pigment during the preparation of the protective layer composition.

The dispersant may comprise a nonionic dispersant, an anionic dispersant, a cationic dispersant, and the like. For example, the dispersant may comprise polyalkylene glycol and an ester thereof, polyoxyalkylene, a polyhydric alcohol ester alkylene oxide adduct, an alcohol alkylene oxide adduct, a sulfonic acid ester, a sulfonate, a carboxylic acid ester, a carboxylate, an alkylamide alkylene oxide adduct, an alkylamine, and the like, and these may be used alone or in a mixture of two or more thereof.

Examples of commercially available products of the dispersant comprise DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like from BYK; EFKA-47, EFKA-47EA, EFKA-48, EFKA-49, EFKA-100, EFKA-400, EFKA-450, and the like from EFKA Chemical; Solsperse 5000, Solsperse 12000, Solsperse 13240, Solsperse 13940, Solsperse 17000, Solsperse 20000, Solsperse 24000GR, Solsperse 27000, Solsperse 28000, and the like from Zeneca; or PB711, PB821, and the like from Ajinomoto.

The dispersant may be included in an amount of 0.1 wt % to 15 wt % based on the total amount of the protective layer composition. When the dispersant is present within the above-described range, the composition exhibits good dispersibility, thereby improving stability, developability, and flatness during the preparation of the protective layer.

The pigment may also be pre-treated using a water-soluble inorganic salt and a wetting agent. When the pigment is pre-treated and used, the average particle diameter of the pigment may be refined.

The pre-treatment may be performed through a step of kneading the pigment with the water-soluble inorganic salt and the wetting agent, and a step of filtering and washing the pigment obtained from the kneading step.

The kneading may be performed at a temperature of 40 °C to 100 °C, and the filtering and washing may be performed by washing the inorganic salt with water or the like and then filtering.

Examples of the water-soluble inorganic salt comprise sodium chloride, potassium chloride, and the like, but are not limited thereto.

The wetting agent may serve as a medium in which the pigment and the water-soluble inorganic salt are uniformly mixed, allowing the pigment to be easily pulverized.

For example, the wetting agent may comprise an alkylene glycol monoalkyl ether such as ethylene glycol monoethyl ether, propylene glycol monomethyl ether, diethylene glycol monomethyl ether, and the like; an alcohol such as ethanol, isopropanol, butanol, hexanol, cyclohexanol, ethylene glycol, diethylene glycol, polyethylene glycol, glycerin polyethylene glycol, and the like, and these may be used alone or in a mixture of two or more thereof.

The pigment that has undergone the kneading step may have an average particle diameter of 20 nm to 110 nm. When the average particle diameter of the pigment is within the above-described range, high heat resistance and light resistance are provided, and fine patterns can be effectively formed.

The pigment may be included in an amount of 1 wt % to 40 wt %, or 2 wt % to 30 wt %, or 3 wt % to 20 wt %, or 5 wt % to 15 wt %, or 7 wt % to 12 wt %, or 7 wt % to 10 wt % based on the total amount of the protective layer composition. When the pigment is included within the above-described range, sufficient color reproducibility is provided, and the curability and adhesion of the coating layer are improved.

### 2. Monomer

In embodiments of the present disclosure, the protective layer composition may comprise a monomer.

The monomer included in the protective layer composition may comprise an acrylate group.

The monomer may be a compound represented by the following Formula 1.

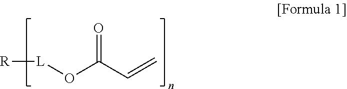

The symbols described in Formula 1 may be defined as follows.

n may be an integer from 1 to 4.

R may be selected from the group consisting of hydrogen; deuterium; a C₁-C₃₀ alkyl group; a C₂-C₃₀ alkenyl group; a C₂-C₃₀ alkynyl group; a C₃-C₃₀ cycloalkyl group; a C₁-C₃₀ ether group; a C₁-C₃₀ ketone group; a C₁-C₃₀ ester group; a C₁-C₃₀ alkoxy group; a C₆-C₃₀ aryl group; a C₂-C₃₀ heterocyclic group comprising at least one heteroatom selected from the group consisting of oxygen (O), nitrogen (N), sulfur(S), silicon (Si), and phosphorus (P); a C₆-C₃₀ aryloxy group; a hydroxy group; and combinations thereof.

L may be selected from the group consisting of a single bond; a C₁-C₃₀ alkylene group; a C₂-C₃₀ alkenylene group; a C₂-C₃₀ alkynylene group; a C₃-C₃₀ cycloalkylene group; a C₁-C₃₀ ether group; a C₁-C₃₀ ketone group; a C₁-C₃₀ ester group; a C₁-C₃₀ alkoxylene group; a C₆-C₃₀ arylene group; a C₂-C₃₀ heterocyclic group comprising at least one heteroatom selected from the group consisting of O, N, S, Si, and P; a C₆-C₃₀ aryloxy group; and combinations thereof.

In R and L of Formula 1, the C₁-C₃₀ alkyl group; the C₂-C₃₀ alkenyl group; the C₂-C₃₀ alkynyl group; the C₃-C₃₀ cycloalkyl group; the C₁-C₃₀ ether group; the C₁-C₃₀ ketone group; the C₁-C₃₀ ester group; the C₁-C₃₀ alkoxy group; the C₆-C₃₀ aryl group; the C₂-C₃₀ heterocyclic group comprising at least one heteroatom selected from the group consisting of O, N, S, Si, and P; and the C₆-C₃₀ aryloxy group may each independently be further substituted with one or more substituents selected from the group consisting of deuterium, a halogen group, a hydroxy group, a nitrile group, a nitro group, a carbonyl group, an ether group, an ester group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P.

The monomer may be at least one of compounds represented by Formulas P-1-1 to P-1-36 below.

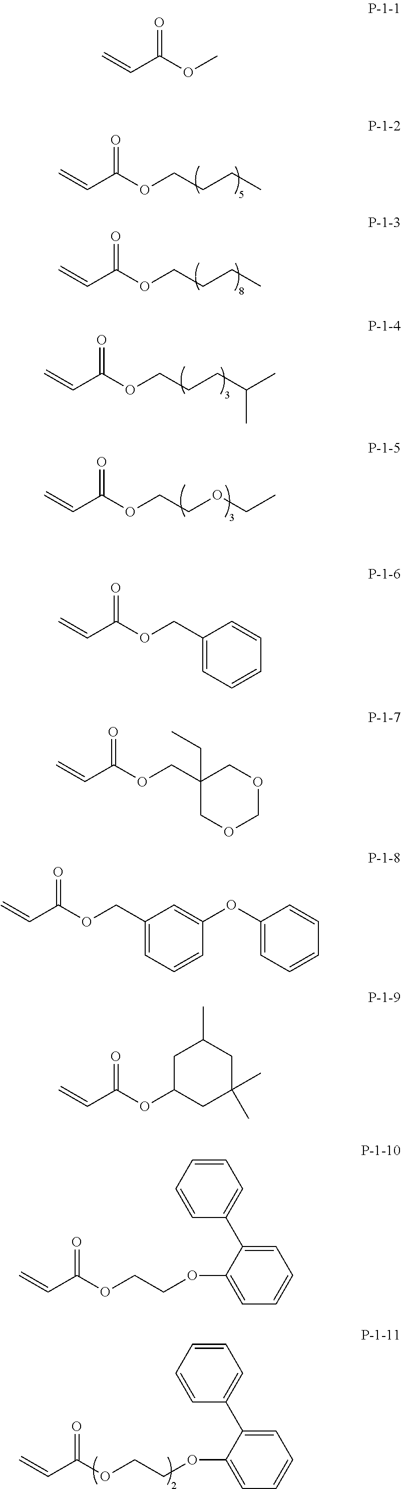

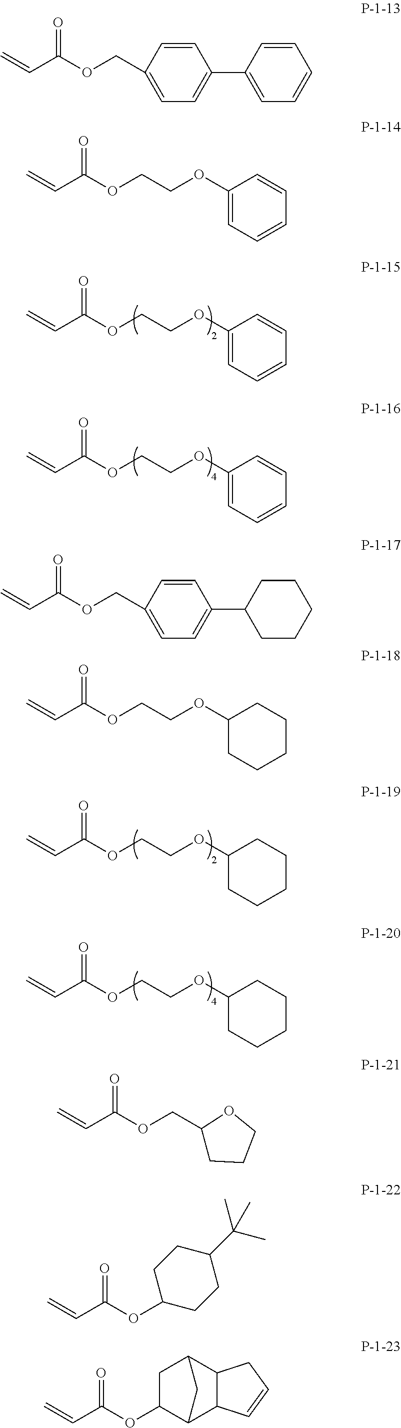

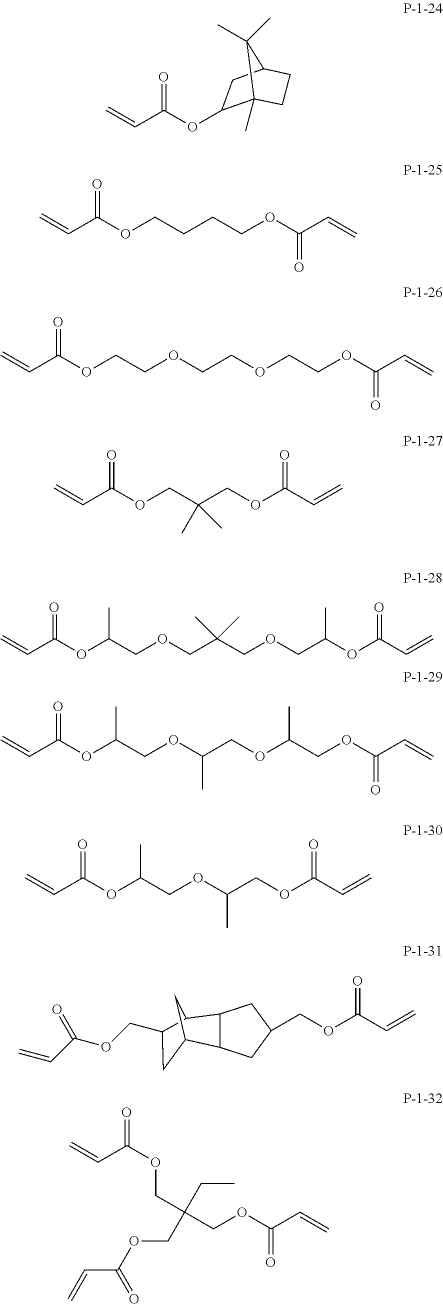

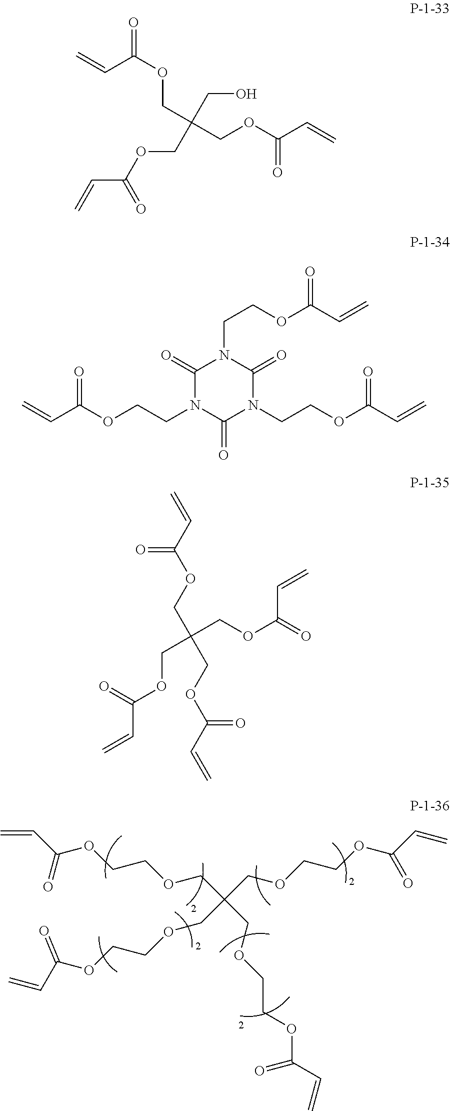

The monomer may be included in an amount of 1 to 40 wt %, 1 to 30 wt %, 1 to 25 wt %, or 5 to 25 wt % with respect to the total amount of the protective layer composition.

When a protective layer composition according to embodiments of the present disclosure includes the above-described monomer, the performance of the protective layer may be significantly improved.

For example, the protective layer composition comprising the above-described monomer may provide strong adhesion, thereby strengthening the bonding force between a display panel and the protective layer.

For example, the protective layer composition comprising the above-described monomer may exhibit increased flexibility due to the characteristics of an acrylate group, and thus may be applied to a flexible display.

For example, due to the optical transparency of an acrylate polymer, the protective layer composition comprising the above-described monomer may perform an effective protective function without affecting the image quality of a display.

Further, due to the heat resistance and moisture resistance of the acrylate polymer, the protective layer composition comprising the above-described monomer may maintain stable performance even in a high-temperature and high-humidity environment, thereby improving the lifespan and reliability of a display.

### 3. Adhesion Promoter

In embodiments of the present disclosure, a protective layer composition may comprise an adhesion promoter.

The adhesion promoter included in the protective layer composition of the present disclosure may comprise silicon (Si).

The adhesion promoter may be a compound represented by the following Formula 2.

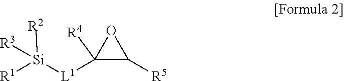

The symbols described in Formula 2 may be defined as follows.

R¹ to R⁵ are each independently selected from the group consisting of hydrogen; deuterium; a C₁-C₃₀ alkyl group; a C₂-C₃₀ alkenyl group; a C₂-C₃₀ alkynyl group; a C₃-C₃₀ cycloalkyl group; a C₁-C₃₀ ether group; a C₁-C₃₀ ketone group; a C₁-C₃₀ ester group; a C₁-C₃₀ alkoxy group; a C₆-C₃₀ aryl group; a C₂-C₃₀ heterocyclic group comprising at least one heteroatom selected from the group consisting of oxygen (O), nitrogen (N), sulfur(S), silicon (Si), and phosphorus (P); a C₆-C₃₀ aryloxy group; and combinations thereof.

L¹ may be selected from the group consisting of a C₁-C₃₀ alkylene group; a C₂-C₃₀ alkenylene group; a C₂-C₃₀ alkynylene group; a C₃-C₃₀ cycloalkylene group; a C₁-C₃₀ ether group; a C₁-C₃₀ ketone group; a C₁-C₃₀ ester group; a C₁-C₃₀ alkoxylene group; a C₆-C₃₀ arylene group; a C₂-C₃₀ heterocyclic group comprising at least one heteroatom selected from the group consisting of O, N, S, Si, and P; a C₆-C₃₀ aryloxy group; and combinations thereof.

Atoms constituting L¹ and R⁵ may be bonded to each other to form a ring.

In R¹ to R⁵ and L¹ of Formula 2, the C₁-C₃₀ alkyl group; the C₂-C₃₀ alkenyl group; the C₂-C₃₀ alkynyl group; the C₃-C₃₀ cycloalkyl group; the C₁-C₃₀ ether group; the C₁-C₃₀ ketone group; the C₁-C₃₀ ester group; the C₁-C₃₀ alkoxy group; the C₆-C₃₀ aryl group; the C₂-C₃₀ heterocyclic group comprising at least one heteroatom selected from the group consisting of O, N, S, Si, and P; and the C₆-C₃₀ aryloxy group may each independently be further substituted with one or more substituents selected from the group consisting of deuterium, a halogen group, a hydroxy group, a nitrile group, a nitro group, a carbonyl group, an ether group, an ester group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P.

The adhesion promoter may be at least one of compounds represented by the following Formulas P-2-1 to P-2-99.

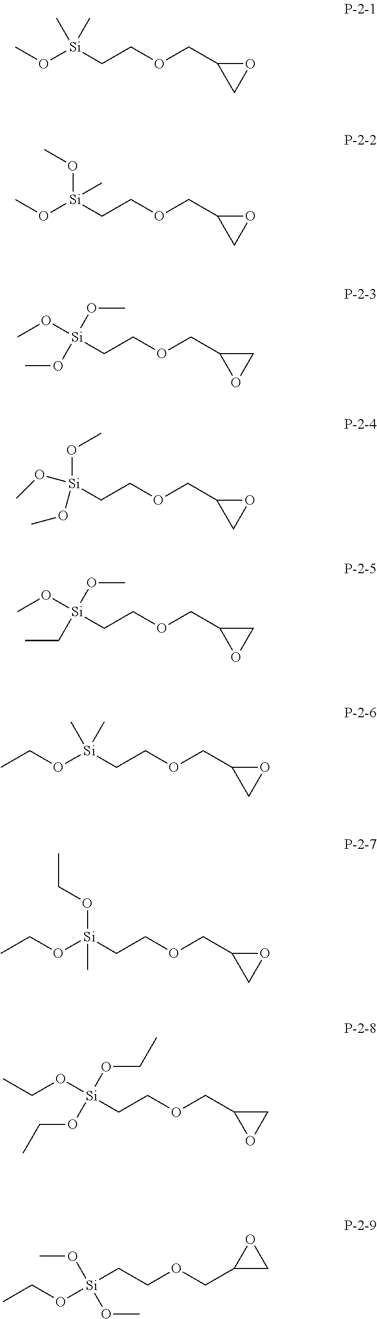

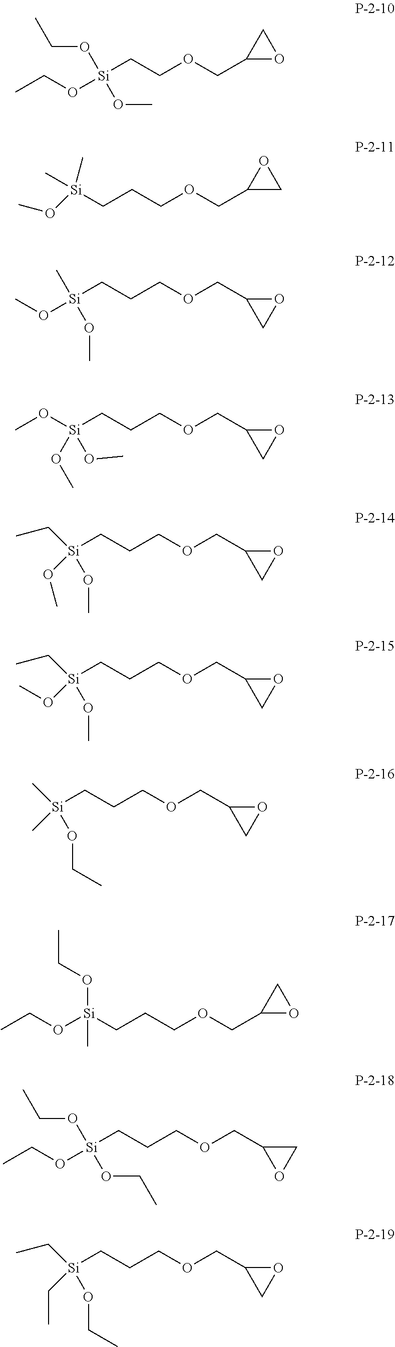

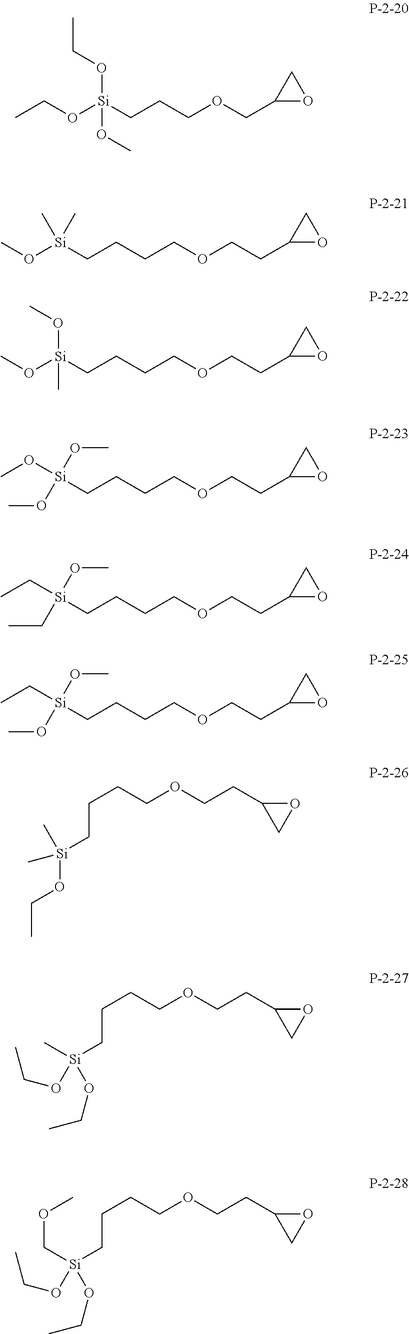

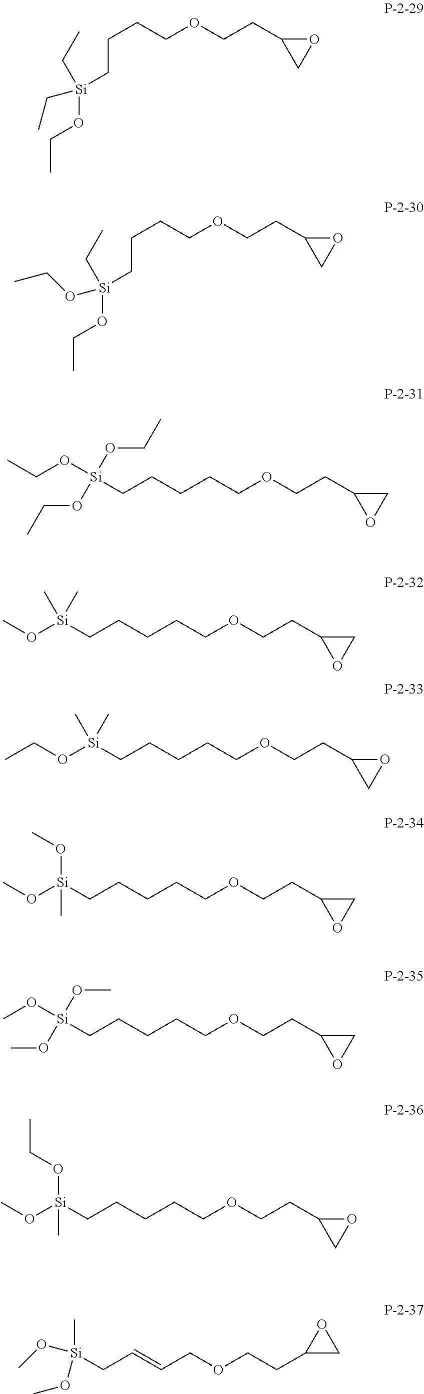

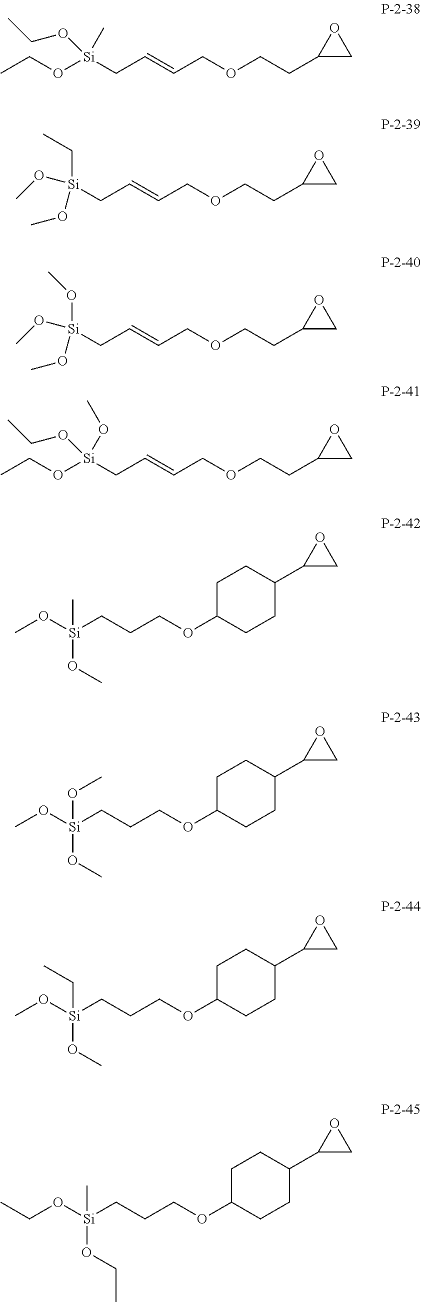

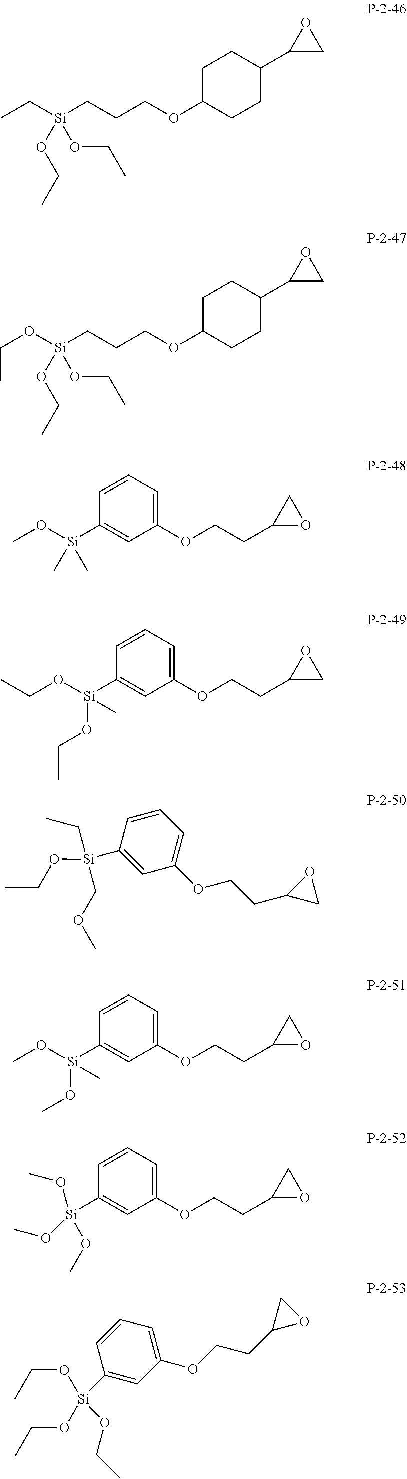

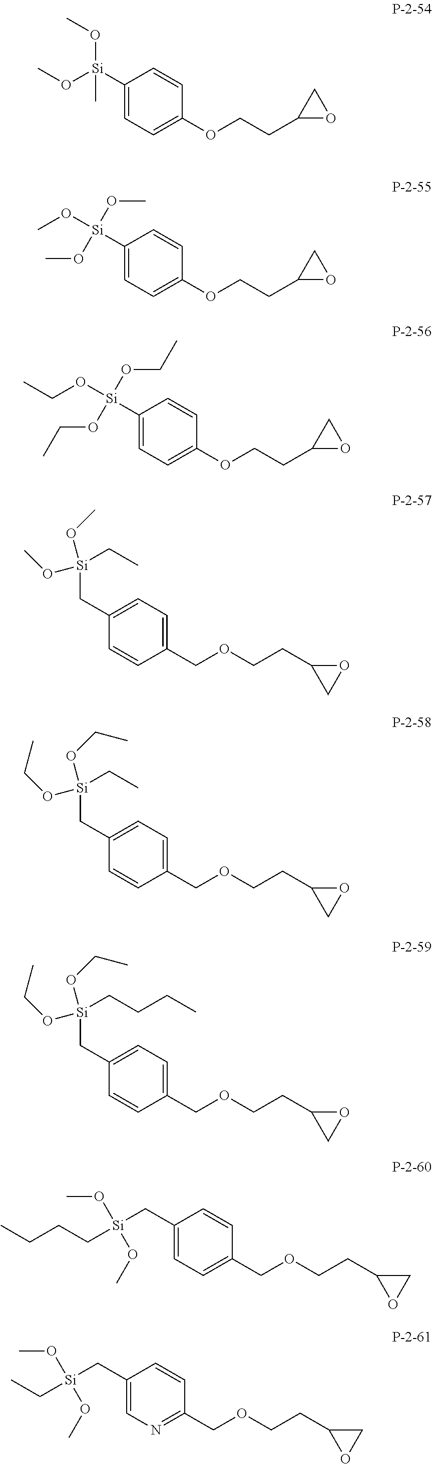

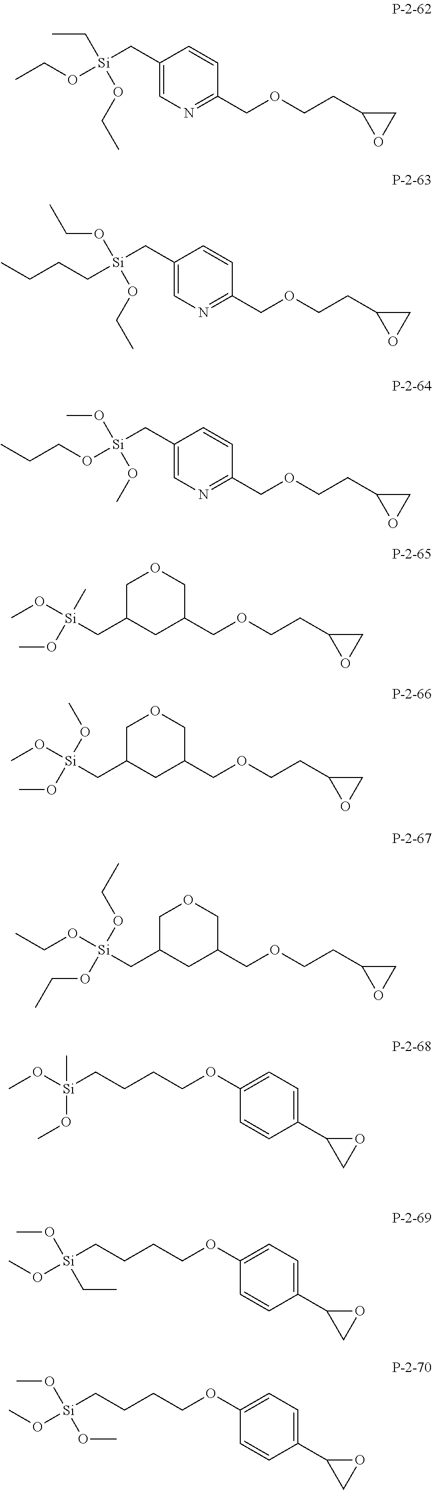

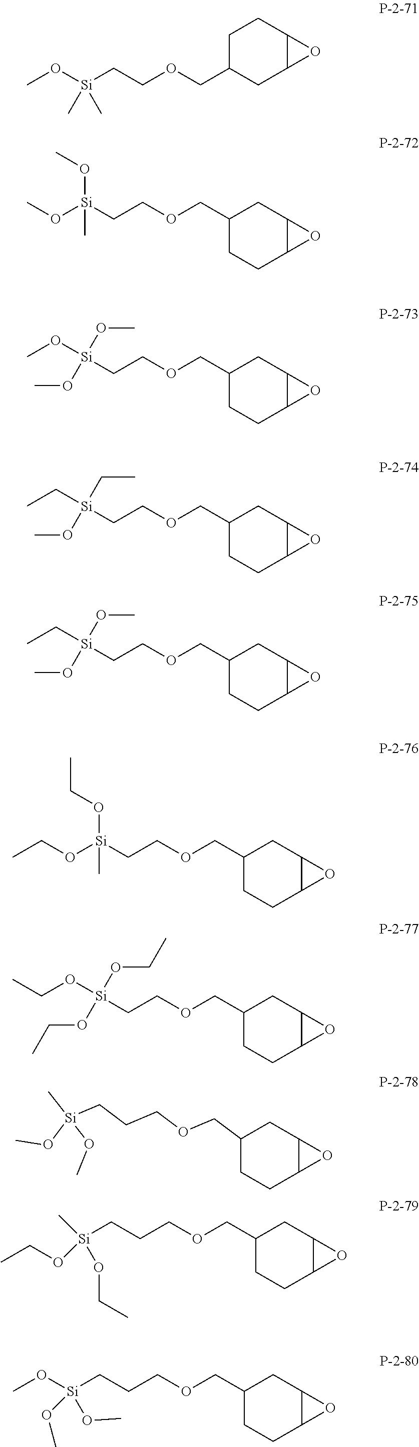

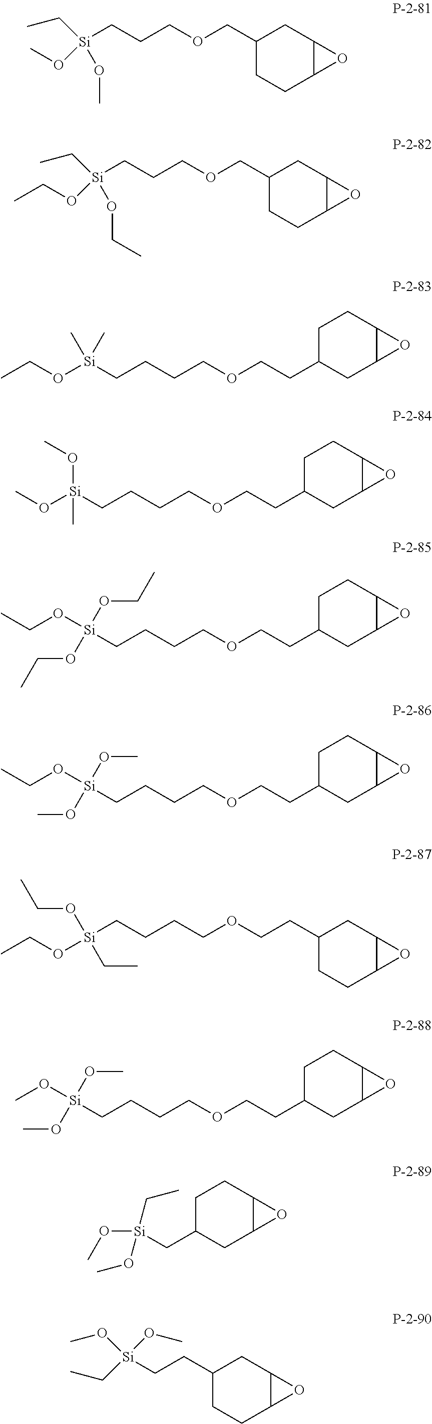

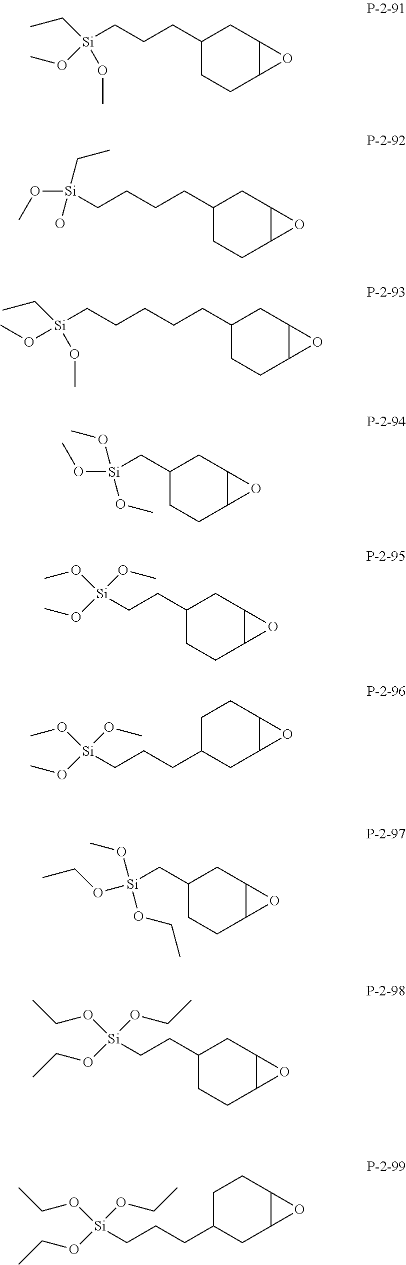

The silicon-based adhesion promoter may be included in an amount of 0.1 to 10 wt %, or 0.1 to 5 wt %, or 0.1 to 3 wt %, or 0.1 to 2 wt %, or 0.5 to 2 wt %, or 0.1 to 1.5 wt %, or 0.5 to 1.5 wt %, or 0.1 to 1.2 wt %, or 0.5 to 1.2 wt % with respect to the total amount of the protective layer composition.

The adhesion promoter comprising silicon used in the present disclosure may significantly improve the performance of the protective layer.

For example, the silicon-based adhesion promoter may enhance the adhesion between a display panel and the protective layer by improving the interfacial bonding strength between organic materials and inorganic materials, thereby reducing peeling of the protective layer and increasing durability.

For example, due to the characteristics of the silicon compound, the silicon-based adhesion promoter improves the heat resistance and moisture resistance of the protective layer, and thus stable performance can be maintained even in a high-temperature and high-humidity environment.

For example, the silicon-based adhesion promoter has good optical transparency, and thus can perform an effective protective function without affecting the image quality of a display.

For example, due to the flexibility of the silicon compound, the silicon-based adhesion promoter can be applied to a flexible display and also provides an antistatic effect, thereby preventing degradation of the performance of the display panel.

### 4. Initiator

In embodiments of the present disclosure, a protective layer composition may comprise an initiator.

For example, the initiator may be used during UV curing, and the initiator may absorb UV or visible light to initiate a polymerization reaction of a monomer or an oligomer.

A photopolymerization initiator is an initiator generally used in the protective layer composition, and representative examples thereof comprise a radical initiator and a cationic initiator.

In the case of the radical initiator, an acetophenone-based compound, a benzophenone-based compound, a thioxanthone-based compound, a benzoin-based compound, a triazine-based compound, an oxime-based compound, a phosphine oxide-based compound, or a mixture thereof may be used. For example, the radical initiator may initiate a radical reaction of an acrylate monomer.

Examples of the acetophenone-based compound comprise 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-morpholinopropan-1-one, and 2-benzyl-2-dimethylamino-1-(4-morpholinophenyl)-butan-1-one.

Examples of the benzophenone-based compound comprise benzophenone, benzoyl benzoic acid, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, and 3,3′-dimethyl-2-methoxybenzophenone.

Examples of the thioxanthone-based compound comprise thioxanthone, 2-chlorothioxanthone, 2-methylthioxanthone, isopropyl thioxanthone, 2,4-diethyl thioxanthone, 2,4-diisopropyl thioxanthone, and 2-chlorothioxanthone.

Examples of the benzoin-based compound comprise benzoin, benzoin methyl ether, benzoin ethyl ether, benzoin isopropyl ether, benzoin isobutyl ether, and benzyldimethylketal.

Examples of the triazine-based compound comprise 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphth-1-yl)-4,6-bis(trichloromethyl)-s-triazine, 2-(4-methoxynaphth-1-yl)-4,6-bis(trichloromethyl)-s-triazine, 2-4-trichloromethyl (piperonyl)-6-triazine, and 2-4-trichloromethyl (4′-methoxystyryl)-6-triazine.

Examples of the oxime-based compound comprise 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, and (E)-1(((3-cyclopentyl-1-(9-ethyl-6-(2-methylbenzoyl)-9H-carbazol-3-yl) propylidene)amino)oxy) ethan-1-one (PBG-304, Trony Co.).

Examples of the phosphine oxide-based compound comprise diphenyl(2,4,6-trimethylbenzoyl)phosphine oxide (TPO), ethyl phenyl (2,4,6-trimethylbenzoyl)phosphinate (TPO-L), and methyl acrylphosphine oxide.

As the photoinitiator, in addition to the compounds described above, a carbazole-based compound, a diketone-based compound, a sulfonium borate-based compound, a diazo-based compound, an imidazole-based compound, a biimidazole-based compound, and the like may be used.

Among the photoinitiators, as a radical polymerization initiator, a peroxide-based compound, an azobis-based compound, and the like may be used.

Examples of the peroxide-based compound comprise ketone peroxides such as methyl ethyl ketone peroxide, methyl isobutyl ketone peroxide, cyclohexanone peroxide, methyl cyclohexanone peroxide, and acetylacetone peroxide; diacyl peroxides such as isobutyryl peroxide, 2,4-dichlorobenzoyl peroxide, o-methylbenzoyl peroxide, and bis-3,5,5-trimethylhexanoyl peroxide; hydroperoxides such as 2,4,4-trimethylpentyl-2-hydroperoxide, diisopropylbenzene hydroperoxide, cumene hydroperoxide, and t-butyl hydroperoxide; dialkyl peroxides such as dicumyl peroxide, 2,5-dimethyl-2,5-di(t-butylperoxy) hexane, 1,3-bis(t-butyloxyisopropyl)benzene, and t-butylperoxyvalerate n-butyl ester; alkyl peresters such as 2,4,4-trimethylpentyl peroxyphenoxyacetate, α-cumyl peroxyneodecanoate, t-butyl peroxybenzoate, and di-t-butyl peroxytriethyladipate; and percarbonates such as di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, and t-butyl peroxyallylcarbonate.

Examples of the azobis-based compound comprise 1,1′-azobiscyclohexane-1-carbonitrile, 2,2′-azobis(2,4-dimethylvaleronitrile), 2,2′-azobis(methyl isobutyrate), 2,2′-azobis(4-methoxy-2,4-dimethylvaleronitrile), α,α′-azobis(isobutylnitrile), and 4,4′-azobis(4-cyanovaleric acid).

In the case of the cationic initiator, it may generate a cation by irradiation with UV or visible light to initiate polymerization, and in particular, it may be used to initiate a radical reaction during polymerization of a monomer such as an epoxy or a vinyl ether. For example, an onium salt initiator and a non-onium salt initiator may be used during monomer polymerization.

Examples of the onium salt initiator include diaryl iodonium salts, triarylsulfonium salts, ferrocenium salts, sulfonium hexafluoroantimony salts, sulfonium hexafluorophosphate salts, and the like.

Examples of the non-onium salt initiator include trifluoromethanesulfonate, tetraphenylborate, iron phenylsulfone, N-hydroxynaphthalimide triflate (NIT), and the like.

Radical initiators and cationic initiators may be classified into primary initiators and secondary initiators according to their roles.

In the case of the primary initiator, it may directly absorb light to generate radicals or cations, thereby inducing an initiation reaction by itself. For example, the primary initiator includes acetophenone-based initiators, triazine-based initiators, and the like.

For example, the acetophenone-based initiator includes acetophenone, 2-hydroxy-2-methylpropiophenone, 1-hydroxycyclohexyl phenyl ketone, 2,2-dimethoxyacetophenone, and the like, but is not limited thereto.

For example, the triazine-based initiator includes 2,4,6-triphenyloxadiazolyl-1,3,5-triazine, hexamethoxymethyltriazine, bis(4-dimethylaminophenyl)-1,3,5-triazine, 2,4,6-triphenyl-1,3,5-triazine, and the like, but is not limited thereto.

The secondary initiator may increase the sensitivity of the primary initiator or play an auxiliary role to enable activation at a longer wavelength, thereby inducing uniform curing of a coating surface. For example, the secondary initiator includes anthracene-based, thioxanthone-based, and coumarin-based photosensitizers, and the like.

Examples of the anthracene-based initiator include 9,10-diphenylanthracene, 1-chloro-9,10-bis(phenylethynyl) anthracene, 2-ethylanthracene, and the like, but are not limited thereto.

Examples of the thioxanthone-based initiator include isopropyl thioxanthone, 2-chlorothioxanthone, 2,4-diethylthioxanthone, and the like, but are not limited thereto.

Examples of the coumarin-based photosensitizer include coumarin 6, 4-methyl-7-diethylaminocoumarin, 3-phenylcoumarin, and the like.

A photoinitiator may also be used together with a photosensitizer that causes a chemical reaction by absorbing light to enter an excited state and then transferring the energy. Examples of the photosensitizer include tetraethylene glycol bis-3-mercaptopropionate, pentaerythritol tetrakis-3-mercaptopropionate, dipentaerythritol tetrakis-3-mercaptopropionate, and the like.

The initiator may be included in an amount of 1 to 40% by weight, for example, 1 to 30% by weight, based on the total weight of the protective layer composition. When the initiator is included within the above-described range, crosslinking of the monomer sufficiently occurs in a protective layer forming process, so that good reliability for a protective effect can be obtained.

### 5. Other Additives

In embodiments of the present disclosure, the protective layer composition may comprise other additives.

For example, in preparing the protective layer composition of the present disclosure, an epoxy-based additive, a leveling agent, and an antistatic agent may be additionally included.

The epoxy-based additive may improve hardness when configuring the protective layer.

The leveling agent may improve surface smoothness. For example, the leveling agent may serve to allow the protective layer composition to spread uniformly on a substrate, and may serve to prevent the protective layer composition from excessively spreading or shrinking through surface tension control.

In addition, it may serve to improve flowability and workability of the protective layer composition in a head of an inkjet printer.

The leveling agent may comprise a silicone-based compound.

A molecular weight of the silicone-based compound may be 5,000 g/mol to 15,000 g/mol.

The molecular weight of the silicone-based compound may be 5,000 g/mol to 10,000 g/mol.

A viscosity of the silicone-based compound may be 100,000 mm²/s to 500,000 mm²/s.

A viscosity of the silicone-based compound when measured at 20 °C for a mixture of 50 wt % of the silicone-based compound and 50 wt % of propylene glycol methyl ether acetate may be 10 mm²/s to 40 mm²/s.

A viscosity of the mixture comprising the silicone-based compound may be 10 mm²/s to 30 mm²/s.

The silicone-based compound may comprise a substituent selected from the group consisting of a C₁-C₄₀ alkyl group; a C₁-C₄₀ alkenyl group; a C₁-C₄₀ alkynyl group; a C₁-C₄₀ alkoxy group; a C₆-C₄₀ aryloxy group; a C₁-C₄₀ alkoxycarbonyl group; a carbonyl group; an ether group; an ester group; a carboxyl group; and combinations thereof.

The antistatic agent may serve to suppress generation of static electricity by controlling surface resistance of the protective layer according to embodiments of the present disclosure, and to prevent dust adhesion and maintain electrical stability.

For example, the antistatic agent includes a polymeric antistatic agent, an ionic antistatic agent, a semi-conductive filler, an inorganic antistatic agent, an organometallic complex antistatic agent, and the like.

Examples of the polymeric antistatic agent include polyethylene glycol, polyoxyethylene, polyvinylpyrrolidone, polyethyleneimide, and the like, but are not limited thereto.

In the case of the ionic antistatic agent, it is classified into a cationic ionic antistatic agent and an anionic ionic antistatic agent. In the case of the cationic antistatic agent, examples include quaternary ammonium salts, imidazolinium salts, pyridinium salts, and the like, and in the case of the anionic antistatic agent, examples include sulfonate salts, carboxylate salts, and the like, but are not limited thereto.

Examples of the semi-conductive filler include carbon black, carbon nanotubes, silver nanowires, and the like, but are not limited thereto.

Examples of the inorganic antistatic agent include indium tin oxide, zinc oxide, titanium oxide, silicon oxide, and the like, but are not limited thereto.

Examples of the organometallic complex antistatic agent include a conductive polymer mixture (PEDOT:PSS), a silver nanoparticle composite, a copper oxide nanocomposite, a graphene-metal composite, and the like, but are not limited thereto.

The other additives described above may be included in an amount of 1 to 10 wt % based on the total weight of the protective layer composition.

According to embodiments of the present disclosure, a protective layer comprising the protective layer composition described above may be provided.

According to embodiments of the present disclosure, a display device comprising the protective layer composition described above may be provided.

Hereinafter, various embodiments of the present disclosure will be described in detail with reference to the accompanying drawings.

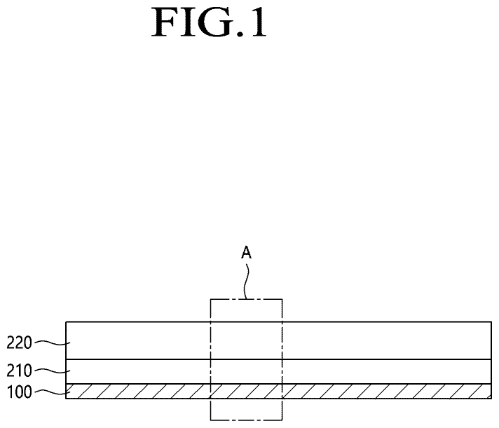

FIG. 1 is an exemplary cross-sectional view schematically illustrating a display device according to embodiments of the present disclosure.

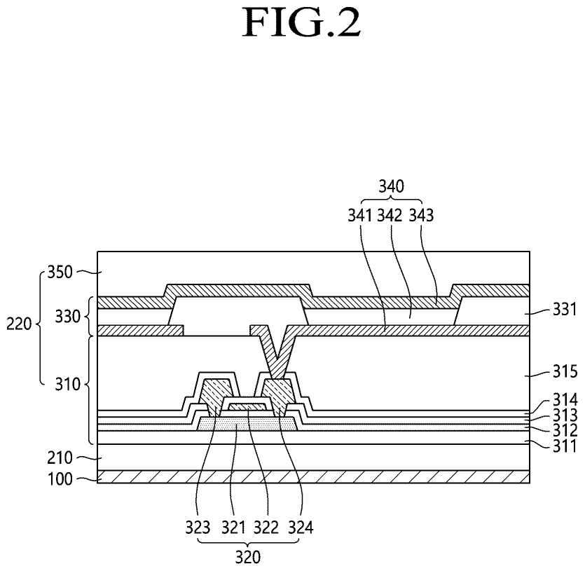

FIG. 2 is an exemplary cross-sectional view illustrating an enlarged cross-section of region A shown in FIG. 1.

Referring to FIGS. 1 and 2, the display device may comprise a protective layer 100, a substrate 210, and a pixel array layer 220. The display device may be a display element, a display panel, or an electronic device. The pixel array layer 220 may comprise a pixel circuit layer 310, a pixel element layer 330, and an encapsulation layer 350.

The protective layer 100 may be disposed under the substrate 210. The protective layer 100 may be disposed on the other surface of the substrate 210 opposite to one surface of the substrate 210 on which the pixel array layer 220 is disposed. The protective layer 100 may comprise a composition comprising the colorant, the monomer, and the adhesion promoter as described above.

By including the colorant, the protective layer 100 may minimize reflection of internal light from the bottom of the display panel, thereby preventing color interference and electrode oxidation. The protective layer 100 may effectively protect sensitive electronic components such as the display panel from external stimuli by improving resistance to external impact, scratches, and abrasion by comprising the monomer and the adhesion promoter.

The substrate 210 may be disposed on the protective layer 100. The substrate 210 may be disposed to directly contact the protective layer 100. The substrate 210 is for supporting various components of the display device and may comprise a light emitting area and a non-light emitting area surrounding the light emitting area. The substrate 210 may be formed of an insulating material such as a glass substrate or a plastic substrate.

The pixel circuit layer 310 may be disposed on the substrate 210. The pixel circuit layer 310 may comprise various insulating layers 311, 312, 313, 314, and 315 and a thin film transistor 320.

The buffer layer 311 may be disposed on the substrate 210. The buffer layer 311 may be a single layer or multiple layers. The buffer layer 311 may serve to delay diffusion of moisture and/or oxygen penetrating into the substrate 210.

The thin film transistor 320 may be disposed on the buffer layer 311. The thin film transistor 320 may comprise an active layer 321, a gate electrode 322, a source electrode 323, and a drain electrode 324.

The active layer 321 may be disposed on the buffer layer 311. The active layer 321 may be composed of a silicon semiconductor, an oxide semiconductor, or an organic semiconductor.

The gate insulating layer 312 may be disposed on a portion of a top surface and a side surface of the active layer 321. The gate insulating layer 312 may also be disposed on the buffer layer 311. The gate insulating layer 312 may be formed of an inorganic insulating material.

The gate electrode 322 may be disposed on the gate insulating layer 312. The gate electrode 322 may comprise various conductive materials. For example, the gate electrode 322 may comprise a metal or an alloy, or may comprise a transparent conductive material. The gate electrode 322 may have a single-layer or multi-layer structure.

A region where the active layer 321 overlaps the gate electrode 322 may be a channel region of the thin film transistor 320, and a region where the active layer 321 does not overlap the gate electrode 322 may be a conductive region.

An interlayer insulating layer 313 may be disposed on the gate electrode 322. The interlayer insulating layer 313 may also be disposed on the gate insulating layer 312. The interlayer insulating layer 313 may be formed of an inorganic insulating material.

A source electrode 323 and a drain electrode 324 may be disposed on the interlayer insulating layer 313. The source electrode 323 and the drain electrode 324 may be electrically and physically connected to the conductive region of the active layer 321.

The source electrode 323 and the drain electrode 324 may be electrically and physically connected to the conductive region of the active layer 321, respectively, through contact holes penetrating the gate insulating layer 312 and the interlayer insulating layer 313.

Although FIG. 2 illustrates that the drain electrode 324 is connected to an anode electrode 341 of a light emitting element 340, the source electrode 323 may be connected to the anode electrode 341.

The source electrode 323 and the drain electrode 324 may each comprise various conductive materials. For example, the source electrode 323 and the drain electrode 324 may comprise a metal or an alloy, or may comprise a transparent conductive material. The source electrode 323 and the drain electrode 324 may have a single-layer or multi-layer structure.

A passivation layer 314 for insulating the thin film transistor 320 may be disposed on the source electrode 323 and the drain electrode 324. The passivation layer 314 may also be disposed on the interlayer insulating layer 313. The passivation layer 314 may be formed of an inorganic insulating material.

A planarization layer 315 may be disposed on the passivation layer 314. The planarization layer 315 may be formed of an organic insulating material. The planarization layer 315 may have a single-layer or multi-layer structure.

A pixel element layer 330 may be disposed on the planarization layer 315. The pixel element layer 330 may comprise the light emitting element 340 and a pixel defining layer 331. The light emitting element 340 may comprise the anode electrode 341, a light emitting layer 342, and a cathode electrode 343.

The anode electrode 341 may be disposed on the planarization layer 315.

The anode electrode 341 may be electrically and physically connected to the drain electrode 324 of the thin film transistor 320 through a contact hole penetrating the planarization layer 315 and the passivation layer 314.

The pixel defining layer 331 may be formed at boundaries of sub-pixel regions. The pixel defining layer 331 may be formed on the planarization layer 315 to cover an edge of the anode electrode 341 in order to partition the sub-pixel regions. The pixel defining layer 331 may be formed of an organic insulating material. The pixel defining layer 331 may comprise a black material. When the pixel defining layer 331 comprises a black material, both internal light and external light may be blocked.

The light emitting layer 342 may be formed on the anode electrode 341 and the pixel defining layer 331. The light emitting layer 342 may cover the pixel defining layer 331 and the anode electrode 341 not covered by the pixel defining layer 331.

The light emitting layer 342 may emit any one of red light, green light, blue light, and white light. The light emitting layer 342 may be, for example, a white light emitting layer that emits white light. The light emitting layer 342 may be formed in a tandem structure in which two or more stacks are stacked.

The anode electrode 341 may be a reflective electrode comprising a metal material having a low work function and high reflection efficiency. The anode electrode 341 may comprise a reflective electrode and a transparent electrode disposed on the reflective electrode.

The cathode electrode 343 may be formed on the light emitting layer 342. The cathode electrode 343 may be a transmissive electrode. In addition, the cathode electrode 343 may be a semi-transmissive electrode. The cathode electrode 343 may be formed of a thin metal film having semi-transmissivity of light.

Although not shown, a capping layer may be disposed on the cathode electrode 343.

An encapsulation layer 350 may be disposed on the pixel element layer 330.

The encapsulation layer 350 may be disposed on the cathode electrode 343. The encapsulation layer may be a single layer or a multi-layer structure. The encapsulation layer 350 may be formed by alternately stacking a plurality of inorganic films and organic films.

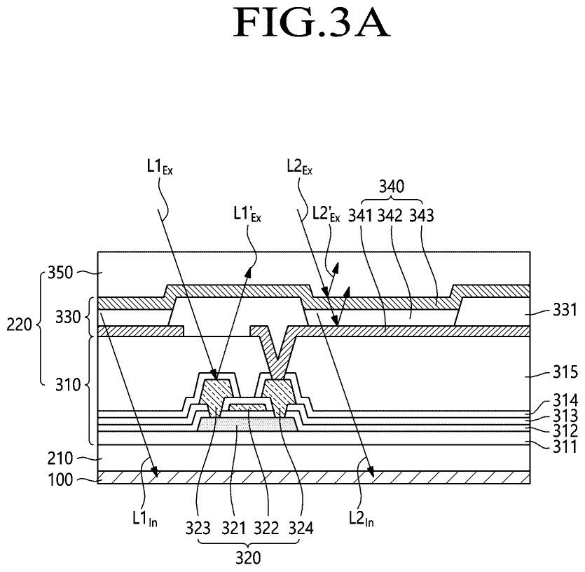

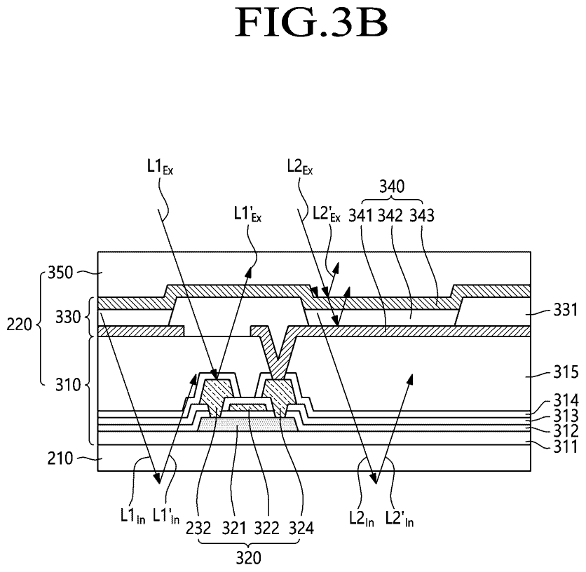

FIGS. 3A and 3B are exemplary views illustrating optical paths in a display device according to embodiments of the present disclosure and a display device according to a comparative example. FIG. 3A illustrates light paths of external light and internal light in a display device according to embodiments of the present disclosure, and FIG. 3B illustrates light paths of external light and internal light in a display device according to a comparative example.

Referring to FIG. 3A, a portion of first external light L1_{EX} incident on a pixel defining layer 331 may be reflected by a metal layer comprising a thin film transistor 320 and emitted to the outside as emitted light L1′_{EX}. Further, a portion of second external light L2_{EX} incident on the light emitting layer 342 may be reflected by the anode electrode 341 and the cathode electrode 343 and emitted to the outside as emitted light L2′_{EX}.

In the case of a top emission type, internal light emitted from the light emitting layer 342 may be reflected by the anode electrode 341 and emitted toward a front direction of the display device, which is opposite to a direction of the substrate 210. Meanwhile, some internal light L1_{IN}, L2_{IN} may propagate toward the substrate 210. In this case, the first internal light L1_{IN} and the second internal light L2_{IN} may be shielded or absorbed by a protective layer 100 disposed below the substrate 210. The internal light rays L1_{IN} and L2_{IN} blocked or absorbed by the protective layer 100 may be emitted to the outside of the substrate 210 or may, upon reflection, be prevented from proceeding toward the light emitting layer 342, thereby helping to prevent color interference and oxidation of the electrode.

In contrast, referring to FIG. 3B, some internal light L1_{IN}, L2_{IN} emitted from the light emitting layer 342 and propagating toward the substrate 210 may be reflected from a lower portion of the substrate 210 and propagate to the light emitting layer 342. Such reflected light L1′_{IN}, L2′_{IN} may propagate to the light emitting layer 342 and interfere with light emitted from the light emitting layer 342, which may cause a color interference phenomenon. Further, there may be a problem in which oxidation of electrodes occurs due to light incident from the lower portion of the substrate 210.

According to embodiments of the present disclosure, the protective layer may have high adhesion and light shielding performance by comprising a colorant, a monomer, and an adhesion promoter. Accordingly, color interference due to internal light and external light and oxidation of electrodes may be prevented, thereby improving reliability of the display device.

Further, the protective layer may prevent degradation of display performance by improving durability and reliability of the display device through enhanced adhesion.

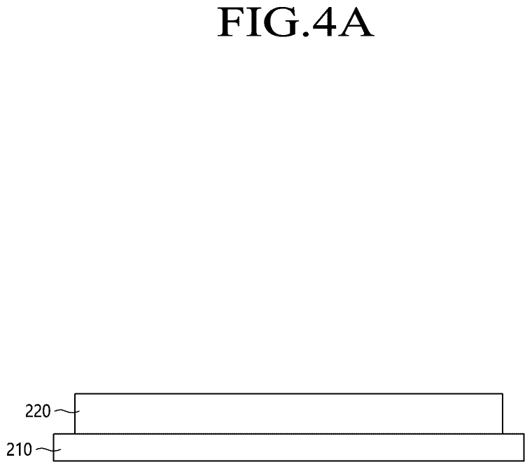

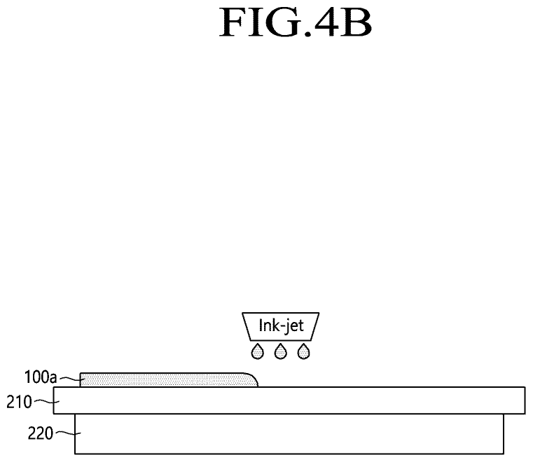

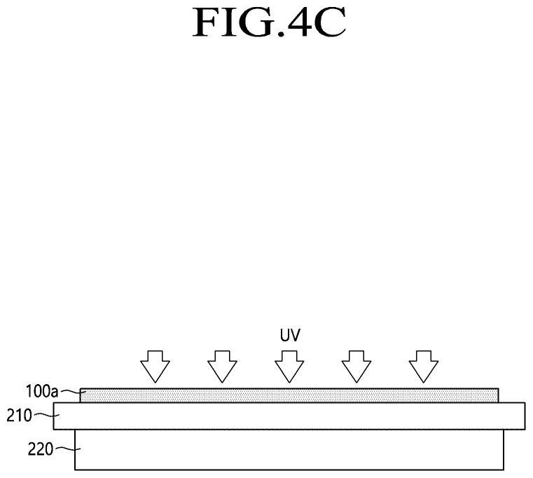

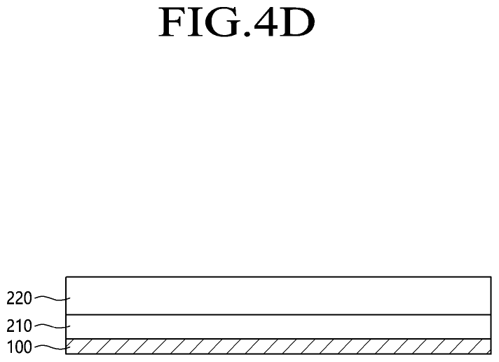

FIGS. 4A to 4D are exemplary process diagrams schematically illustrating manufacturing steps of a display device according to embodiments of the present disclosure.

A protective layer according to embodiments of the present disclosure may be formed by processing a protective layer composition, which is an ultraviolet (UV) curable ink composition, by an inkjet printing method. A method of forming the protective layer according to embodiments of the present disclosure may comprise a step of preparing a display panel or a substrate, a step of coating an ink composition comprising the protective layer composition, and a step of curing the coating layer.

Referring to FIG. 4A, first, a step of preparing a substrate 210 may be included. The substrate 210 may be surface-treated so that an ink composition may be easily coated thereon. Coating performance may be improved by surface-treating the substrate 210 according to surface energy of the substrate 210. For example, the substrate 210 may be surface-treated by cleaning, UV ozone, plasma, or the like. Meanwhile, the substrate 210 may be prepared in a display panel state in which a pixel array layer 220 is formed on one surface of the substrate 210.

Referring to FIG. 4B, a coating layer 100a may be formed by coating an ink composition on the substrate 210. The coating layer 100a may be formed on the other surface of the substrate 210 on which the pixel array layer 220 is not disposed.

The coating layer 100a may be formed using an inkjet printing method. An ink composition comprising the protective layer composition may be prepared and supplied to an inkjet printer head, and the ink composition may be discharged such that a thickness of the coating layer is 1 to 100 μm. In this case, for stable discharge of the ink composition from the inkjet printer head, the ink composition may have a low viscosity of about 35 cP.

Referring to FIG. 4C, the coating layer 100a may be exposed to ultraviolet (UV) light to proceed with a curing process, thereby forming a protective layer. The UV light may be irradiated using a UV-LED light lamp. Considering spreadability of the ink composition, the UV curing process may be performed immediately after coating the ink composition.

For example, the UV curing process may be performed under conditions where a distance between the UV-LED light lamp and the coating layer is about 10 cm, an integrated light amount is about 3 J/cm², and a wavelength range is 250 to 400 nm.

Referring to FIG. 4D, the substrate 210 having the protective layer 100 formed on the lower portion thereof may be cut into cell units. The substrate 210 may be cut into a plurality of cell units. The cutting process may be performed using a wheel or a laser.

Hereinafter, synthesis examples of compounds represented by the above formulas according to the present disclosure and examples using the same will be described in detail, but the present disclosure is not limited to the following synthesis examples and examples.

### Synthesis Examples

The compounds represented by Formula 2 according to the present disclosure may be synthesized through Reaction Scheme 1 below, but the compounds represented by Formula 2 according to the present disclosure are not limited to being produced through this reaction scheme.

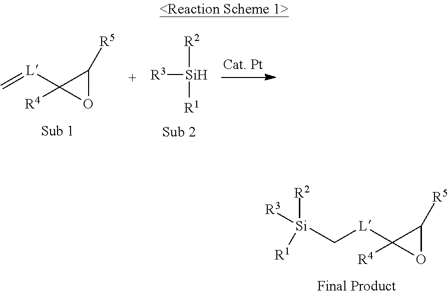

In Sub 1, the definition of L′ is the same as the definition of L¹ in Formula 2. In Sub 1, the definitions of R⁴ and R⁵ are the same as the definitions of R⁴ and R⁵ in Formula 2, respectively.

In Sub 2, the definitions of R¹, R², and R³ are the same as the definitions of R¹, R², and R³ in Formula 2, respectively.

Specifically, the compound P-2-13 represented by Formula 2 according to the present disclosure was prepared through Reaction Scheme 2 below.

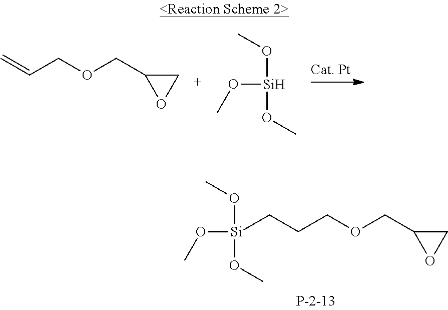

Into a reactor, 200 mL of toluene and 100 g of allyl glycidyl ether were introduced, a Pt catalyst was introduced, and then moisture was removed through N₂ gas purging.

The reactor was heated to 60 °C to 100 °C, 107 g of trimethoxysilane dissolved in 100 mL of toluene was added dropwise, and after reacting for 2 hours to 4 hours, P-2-13 was synthesized through vacuum distillation.

### EXAMPLES

### 1. Preparation of Black Colorant

15 g of Carbon Black W-7016 (Basf), 8.5 g of Disperbyk 163 (BYK), and 6.5 g of SR-3613 (SMS) together with 70 g of propylene glycol methyl ether acetate were dispersed for 10 hours using a paint shaker (Asada) with 100 g of zirconia beads (Toray) having a diameter of 0.5 mm to obtain a dispersion.

### 2. Preparation of Protective Layer Composition

Protective layer compositions for a lower portion of a panel were prepared with the compositions (wt %) shown in Table 1 below.

TABLE 1

| | P-1 | P-2 | P-3 | P-4 | P-5 | P-6 | P-7 | P-8 | P-9 | P-10 |
|---|---|---|---|---|---|---|---|---|---|---|
| Black | 10 | 10 | 10 | 10 | 10 | 10 | 10 | 10 | 10 | 10 |
| colorant | | | | | | | | | | |
| P-1-24 | 25.15 | 25.15 | 25.15 | 25.15 | 25.15 | 25.15 | 25.15 | 25.15 | 25.15 | 25.15 |
| P-2-3 | 0.10 | | | | | | | | | |
| P-2-8 | | 0.10 | | | | | | | | |
| P-2-12 | | | 0.10 | | | | | | | |
| P-2-13 | | | | 0.10 | | | | | | |
| P-2-18 | | | | | 0.10 | | | | | |
| P-2-23 | | | | | | 0.10 | | | | |
| P-2-27 | | | | | | | 0.10 | | | |
| P-2-30 | | | | | | | | 0.10 | | |
| P-2-33 | | | | | | | | | 0.10 | |
| P-2-36 | | | | | | | | | | 0.10 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-11 | P-12 | P-13 | P-14 | P-15 | P-16 | P-17 | P-18 | P-19 | P-20 |
| Black | 10 | 10 | 10 | 10 | 10 | 10 | 10 | 10 | 10 | 10 |
| colorant | | | | | | | | | | |
| P-1-24 | 25.15 | 25.15 | 25.15 | 25.15 | 25.15 | 25.15 | 25.15 | 25.15 | 25.15 | 25.15 |
| P-2-41 | 0.10 | | | | | | | | | |
| P-2-42 | | 0.10 | | | | | | | | |
| P-2-49 | | | 0.10 | | | | | | | |
| P-2-54 | | | | 0.10 | | | | | | |
| P-2-59 | | | | | 0.10 | | | | | |
| P-2-64 | | | | | | 0.10 | | | | |
| P-2-69 | | | | | | | 0.10 | | | |
| P-2-74 | | | | | | | | 0.10 | | |
| P-2-78 | | | | | | | | | 0.10 | |
| P-2-82 | | | | | | | | | | 0.10 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-21 | P-22 | P-23 | P-24 | P-25 | P-26 | P-27 | P-28 | P-29 | P-30 |
| Black | 10 | 10 | 10 | 10 | 10 | 10 | 10 | 10 | 10 | 10 |
| colorant | | | | | | | | | | |
| P-1-24 | 25.15 | 25.15 | 25.15 | 25.15 | 25.15 | | | | | |
| P-1-18 | | | | | | 25.15 | 25.15 | 25.15 | 25.15 | 25.15 |
| P-2-3 | | | | | | 0.10 | | | | |
| P-2-8 | | | | | | | 0.10 | | | |
| P-2-12 | | | | | | | | 0.10 | | |
| P-2-13 | | | | | | | | | 0.10 | |
| P-2-18 | | | | | | | | | | 0.10 |
| P-2-84 | 0.10 | | | | | | | | | |
| P-2-85 | | 0.10 | | | | | | | | |
| P-2-91 | | | 0.10 | | | | | | | |
| P-2-96 | | | | 0.10 | | | | | | |
| P-2-99 | | | | | 0.10 | | | | | |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-31 | P-32 | P-33 | P-34 | P-35 | P-36 | P-37 | P-38 | P-39 | P-40 |
| Black | 10 | 10 | 10 | 10 | 10 | 10 | 10 | 10 | 10 | 10 |
| colorant | | | | | | | | | | |
| P-1-18 | 24.75 | 24.75 | 24.75 | 24.75 | 24.75 | 24.75 | 24.75 | 24.75 | 24.75 | 24.75 |
| P-2-23 | 0.50 | | | | | | | | | |
| P-2-27 | | 0.50 | | | | | | | | |
| P-2-30 | | | 0.50 | | | | | | | |
| P-2-33 | | | | 0.50 | | | | | | |
| P-2-36 | | | | | 0.50 | | | | | |
| P-2-41 | | | | | | 0.50 | | | | |
| P-2-42 | | | | | | | 0.50 | | | |
| P-2-49 | | | | | | | | 0.50 | | |
| P-2-54 | | | | | | | | | 0.50 | |
| P-2-59 | | | | | | | | | | 0.50 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-41 | P-42 | P-43 | P-44 | P-45 | P-46 | P-47 | P-48 | P-49 | P-50 |
| Black | 10 | 10 | 10 | 10 | 10 | 10 | 10 | 10 | 10 | 10 |
| colorant | | | | | | | | | | |
| P-1-18 | 24.75 | 24.75 | 24.75 | 24.75 | 24.75 | 24.75 | 24.75 | 24.75 | 24.75 | 24.75 |
| P-2-64 | 0.50 | | | | | | | | | |
| P-2-69 | | 0.50 | | | | | | | | |
| P-2-74 | | | 0.50 | | | | | | | |
| P-2-78 | | | | 0.50 | | | | | | |
| P-2-82 | | | | | 0.50 | | | | | |
| P-2-84 | | | | | | 0.50 | | | | |
| P-2-85 | | | | | | | 0.50 | | | |
| P-2-91 | | | | | | | | 0.50 | | |
| P-2-96 | | | | | | | | | 0.50 | |
| P-2-99 | | | | | | | | | | 0.50 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-51 | P-52 | P-53 | P-54 | P-55 | P-56 | P-57 | P-58 | P-59 | P-60 |
| Black | 10 | 10 | 10 | 10 | 10 | 10 | 10 | 10 | 10 | 10 |
| colorant | | | | | | | | | | |
| P-1-10 | 24.75 | 24.75 | 24.75 | 24.75 | 24.75 | 24.75 | 24.75 | 24.75 | 24.75 | 24.75 |
| P-2-3 | 0.50 | | | | | | | | | |
| P-2-8 | | 0.50 | | | | | | | | |
| P-2-12 | | | 0.50 | | | | | | | |
| P-2-13 | | | | 0.50 | | | | | | |
| P-2-18 | | | | | 0.50 | | | | | |
| P-2-23 | | | | | | 0.50 | | | | |
| P-2-27 | | | | | | | 0.50 | | | |
| P-2-30 | | | | | | | | 0.50 | | |
| P-2-33 | | | | | | | | | 0.50 | |
| P-2-36 | | | | | | | | | | 0.50 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-61 | P-62 | P-63 | P-64 | P-65 | P-66 | P-67 | P-68 | P-69 | P-70 |
| Black | 10 | 10 | 10 | 10 | 10 | 10 | 10 | 10 | 10 | 10 |
| colorant | | | | | | | | | | |
| P-1-10 | 24.50 | 24.50 | 24.50 | 24.50 | 24.50 | 24.50 | 24.50 | 24.50 | 24.50 | 24.50 |
| P-2-41 | 0.75 | | | | | | | | | |
| P-2-42 | | 0.75 | | | | | | | | |
| P-2-49 | | | 0.75 | | | | | | | |
| P-2-54 | | | | 0.75 | | | | | | |
| P-2-59 | | | | | 0.75 | | | | | |
| P-2-64 | | | | | | 0.75 | | | | |
| P-2-69 | | | | | | | 0.75 | | | |
| P-2-74 | | | | | | | | 0.75 | | |
| P-2-78 | | | | | | | | | 0.75 | |
| P-2-82 | | | | | | | | | | 0.75 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-71 | P-72 | P-73 | P-74 | P-75 | P-76 | P-77 | P-78 | P-79 | P-80 |
| Black | 10 | 10 | 10 | 10 | 10 | 10 | 10 | 10 | 10 | 10 |
| colorant | | | | | | | | | | |
| P-1-10 | 24.50 | 24.50 | 24.50 | 24.50 | 24.50 | | | | | |
| P-1-7 | | | | | | 24.50 | 24.50 | 24.50 | 24.50 | 24.50 |
| P-2-3 | | | | | | 0.75 | | | | |
| P-2-8 | | | | | | | 0.75 | | | |
| P-2-12 | | | | | | | | 0.75 | | |
| P-2-13 | | | | | | | | | 0.75 | |
| P-2-18 | | | | | | | | | | 0.75 |
| P-2-84 | 0.75 | | | | | | | | | |
| P-2-85 | | 0.75 | | | | | | | | |
| P-2-91 | | | 0.75 | | | | | | | |
| P-2-96 | | | | 0.75 | | | | | | |
| P-2-99 | | | | | 0.75 | | | | | |
| Epoxy- | | | | | | | | | | |
| based | | | | | | | | | | |
| additive | | | | | | | | | | |
| TTA- | 22.10 | 22.10 | 22.10 | 22.10 | 22.10 | 22.10 | 22.10 | 22.10 | 22.10 | 22.10 |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-81 | P-82 | P-83 | P-84 | P-85 | P-86 | P-87 | P-88 | P-89 | P-90 |
| Black | 10 | 10 | 10 | 10 | 10 | 10 | 10 | 10 | 10 | 10 |
| colorant | | | | | | | | | | |
| P-1-7 | 24.50 | 24.50 | 24.50 | 24.50 | 24.50 | 24.50 | 24.50 | 24.50 | 24.50 | 24.50 |
| P-2-23 | 0.75 | | | | | | | | | |
| P-2-27 | | 0.75 | | | | | | | | |
| P-2-30 | | | 0.75 | | | | | | | |
| P-2-33 | | | | 0.75 | | | | | | |
| P-2-36 | | | | | 0.75 | | | | | |
| P-2-41 | | | | | | 0.75 | | | | |
| P-2-42 | | | | | | | 0.75 | | | |
| P-2-49 | | | | | | | | 0.75 | | |
| P-2-54 | | | | | | | | | 0.75 | |
| P-2-59 | | | | | | | | | | 0.75 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-91 | P-92 | P-93 | P-94 | P-95 | P-96 | P-97 | P-98 | P-99 | P-100 |
| Black | 10 | 10 | 10 | 10 | 10 | 10 | 10 | 10 | 10 | 10 |
| colorant | | | | | | | | | | |
| P-1-7 | 24.25 | 24.25 | 24.25 | 24.25 | 24.25 | 24.25 | 24.25 | 24.25 | 24.25 | 24.25 |
| P-2-64 | 1 | | | | | | | | | |
| P-2-69 | | 1 | | | | | | | | |
| P-2-74 | | | 1 | | | | | | | |
| P-2-78 | | | | 1 | | | | | | |
| P-2-82 | | | | | 1 | | | | | |
| P-2-84 | | | | | | 1 | | | | |
| P-2-85 | | | | | | | 1 | | | |
| P-2-91 | | | | | | | | 1 | | |
| P-2-96 | | | | | | | | | 1 | |
| P-2-99 | | | | | | | | | | 1 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-101 | P-102 | P-103 | P-104 | P-105 | P-106 | P-107 | P-108 | P-109 | P-110 |
| Black | 10 | 10 | 10 | 10 | 10 | 10 | 10 | 10 | 10 | 10 |
| colorant | | | | | | | | | | |
| P-1-8 | 24.25 | 24.25 | 24.25 | 24.25 | 24.25 | 24.25 | 24.25 | 24.25 | 24.25 | 24.25 |
| P-2-3 | 1 | | | | | | | | | |
| P-2-8 | | 1 | | | | | | | | |
| P-2-12 | | | 1 | | | | | | | |
| P-2-13 | | | | 1 | | | | | | |
| P-2-18 | | | | | 1 | | | | | |
| P-2-23 | | | | | | 1 | | | | |
| P-2-27 | | | | | | | 1 | | | |
| P-2-30 | | | | | | | | 1 | | |
| P-2-33 | | | | | | | | | 1 | |
| P-2-36 | | | | | | | | | | 1 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-111 | P-112 | P-113 | P-114 | P-115 | P-116 | P-117 | P-118 | P-119 | P-120 |
| Black | 10 | 10 | 10 | 10 | 10 | 10 | 10 | 10 | 10 | 10 |
| colorant | | | | | | | | | | |
| P-1-8 | 24.25 | 24.25 | 24.25 | 24.25 | 24.25 | 24.25 | 24.25 | 24.25 | 24.25 | 24.25 |
| P-2-41 | 1 | | | | | | | | | |
| P-2-42 | | 1 | | | | | | | | |
| P-2-49 | | | 1 | | | | | | | |
| P-2-54 | | | | 1 | | | | | | |
| P-2-59 | | | | | 1 | | | | | |
| P-2-64 | | | | | | 1 | | | | |
| P-2-69 | | | | | | | 1 | | | |
| P-2-74 | | | | | | | | 1 | | |
| P-2-78 | | | | | | | | | 1 | |
| P-2-82 | | | | | | | | | | 1 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-121 | P-122 | P-123 | P-124 | P-125 | P-126 | P-127 | P-128 | P-129 | P-130 |
| Black | 10 | 10 | 10 | 10 | 10 | 10 | 10 | 10 | 10 | 10 |
| colorant | | | | | | | | | | |
| P-1-8 | 24.05 | 24.05 | 24.05 | 24.05 | 24.05 | | | | | |
| P-1-3 | | | | | | 24.05 | 24.05 | 24.05 | 24.05 | 24.05 |
| P-2-3 | | | | | | 1.20 | | | | |
| P-2-8 | | | | | | | 1.20 | | | |
| P-2-12 | | | | | | | | 1.20 | | |
| P-2-13 | | | | | | | | | 1.20 | |
| P-2-18 | | | | | | | | | | 1.20 |
| P-2-84 | 1.20 | | | | | | | | | |
| P-2-85 | | 1.20 | | | | | | | | |
| P-2-91 | | | 1.20 | | | | | | | |
| P-2-96 | | | | 1.20 | | | | | | |
| P-2-99 | | | | | 1.20 | | | | | |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-131 | P-132 | P-133 | P-134 | P-135 | P-136 | P-137 | P-138 | P-139 | P-140 |
| Black | 10 | 10 | 10 | 10 | 10 | 10 | 10 | 10 | 10 | 10 |
| colorant | | | | | | | | | | |
| P-1-3 | 24.05 | 24.05 | 24.05 | 24.05 | 24.05 | 24.05 | 24.05 | 24.05 | 24.05 | 24.05 |
| P-2-23 | 1.20 | | | | | | | | | |
| P-2-27 | | 1.20 | | | | | | | | |
| P-2-30 | | | 1.20 | | | | | | | |
| P-2-33 | | | | 1.20 | | | | | | |
| P-2-36 | | | | | 1.20 | | | | | |
| P-2-41 | | | | | | 1.20 | | | | |
| P-2-42 | | | | | | | 1.20 | | | |
| P-2-49 | | | | | | | | 1.20 | | |
| P-2-54 | | | | | | | | | 1.20 | |
| P-2-59 | | | | | | | | | | 1.20 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-141 | P-142 | P-143 | P-144 | P-145 | P-146 | P-147 | P-148 | P-149 | P-150 |
| Black | 10 | 10 | 10 | 10 | 10 | 10 | 10 | 10 | 10 | 10 |
| colorant | | | | | | | | | | |
| P-1-3 | 24.05 | 24.05 | 24.05 | 24.05 | 24.05 | 24.05 | 24.05 | 24.05 | 24.05 | 24.05 |
| P-2-64 | 1.20 | | | | | | | | | |
| P-2-69 | | 1.20 | | | | | | | | |
| P-2-74 | | | 1.20 | | | | | | | |
| P-2-78 | | | | 1.20 | | | | | | |
| P-2-82 | | | | | 1.20 | | | | | |
| P-2-84 | | | | | | 1.20 | | | | |
| P-2-85 | | | | | | | 1.20 | | | |
| P-2-91 | | | | | | | | 1.20 | | |
| P-2-96 | | | | | | | | | 1.20 | |
| P-2-99 | | | | | | | | | | 1.20 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-151 | P-152 | P-153 | P-154 | P-155 | P-156 | P-157 | P-158 | P-159 | P-160 |
| Black | 10 | 10 | 10 | 10 | 10 | 10 | 10 | 10 | 10 | 10 |
| colorant | | | | | | | | | | |
| P-1-6 | 23.75 | 23.75 | 23.75 | 23.75 | 23.75 | 23.75 | 23.75 | 23.75 | 23.75 | 23.75 |
| P-2-3 | 1.50 | | | | | | | | | |
| P-2-8 | | 1.50 | | | | | | | | |
| P-2-12 | | | 1.50 | | | | | | | |
| P-2-13 | | | | 1.50 | | | | | | |
| P-2-18 | | | | | 1.50 | | | | | |
| P-2-23 | | | | | | 1.50 | | | | |
| P-2-27 | | | | | | | 1.50 | | | |
| P-2-30 | | | | | | | | 1.50 | | |
| P-2-33 | | | | | | | | | 1.50 | |
| P-2-36 | | | | | | | | | | 1.50 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-161 | P-162 | P-163 | P-164 | P-165 | P-166 | P-167 | P-168 | P-169 | P-170 |
| Black | 10 | 10 | 10 | 10 | 10 | 10 | 10 | 10 | 10 | 10 |
| colorant | | | | | | | | | | |
| P-1-6 | 23.75 | 23.75 | 23.75 | 23.75 | 23.75 | 23.75 | 23.75 | 23.75 | 23.75 | 23.75 |
| P-2-41 | 1.50 | | | | | | | | | |
| P-2-42 | | 1.50 | | | | | | | | |
| P-2-49 | | | 1.50 | | | | | | | |
| P-2-54 | | | | 1.50 | | | | | | |
| P-2-59 | | | | | 1.50 | | | | | |
| P-2-64 | | | | | | 1.50 | | | | |
| P-2-69 | | | | | | | 1.50 | | | |
| P-2-74 | | | | | | | | 1.50 | | |
| P-2-78 | | | | | | | | | 1.50 | |
| P-2-82 | | | | | | | | | | 1.50 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-171 | P-172 | P-173 | P-174 | P-175 | P-176 | P-177 | P-178 | P-179 | P-180 |
| Black | 10 | 10 | 10 | 10 | 10 | 10 | 10 | 10 | 10 | 10 |
| colorant | | | | | | | | | | |
| P-1-6 | 23.75 | 23.75 | 23.75 | 23.75 | 23.75 | | | | | |
| P-1-25 | | | | | | 23.75 | 23.75 | 23.75 | 23.75 | 23.75 |
| P-2-3 | | | | | | 1.50 | | | | |
| P-2-8 | | | | | | | 1.50 | | | |
| P-2-12 | | | | | | | | 1.50 | | |
| P-2-13 | | | | | | | | | 1.50 | |
| P-2-18 | | | | | | | | | | 1.50 |
| P-2-84 | 1.50 | | | | | | | | | |
| P-2-85 | | 1.50 | | | | | | | | |
| P-2-91 | | | 1.50 | | | | | | | |
| P-2-96 | | | | 1.50 | | | | | | |
| P-2-99 | | | | | 1.50 | | | | | |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-181 | P-182 | P-183 | P-184 | P-185 | P-186 | P-187 | P-188 | P-189 | P-190 |
| Black | 10 | 10 | 10 | 10 | 10 | 10 | 10 | 10 | 10 | 10 |
| colorant | | | | | | | | | | |
| P-1-25 | 23.55 | 23.55 | 23.55 | 23.55 | 23.55 | 23.55 | 23.55 | 23.55 | 23.55 | 23.55 |
| P-2-23 | 1.70 | | | | | | | | | |
| P-2-27 | | 1.70 | | | | | | | | |
| P-2-30 | | | 1.70 | | | | | | | |
| P-2-33 | | | | 1.70 | | | | | | |
| P-2-36 | | | | | 1.70 | | | | | |
| P-2-41 | | | | | | 1.70 | | | | |
| P-2-42 | | | | | | | 1.70 | | | |
| P-2-49 | | | | | | | | 1.70 | | |
| P-2-54 | | | | | | | | | 1.70 | |
| P-2-59 | | | | | | | | | | 1.70 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-191 | P-192 | P-193 | P-194 | P-195 | P-196 | P-197 | P-198 | P-199 | P-200 |
| Black | 10 | 10 | 10 | 10 | 10 | 10 | 10 | 10 | 10 | 10 |
| colorant | | | | | | | | | | |
| P-1-25 | 23.55 | 23.55 | 23.55 | 23.55 | 23.55 | 23.55 | 23.55 | 23.55 | 23.55 | 23.55 |
| P-2-64 | 1.70 | | | | | | | | | |
| P-2-69 | | 1.70 | | | | | | | | |
| P-2-74 | | | 1.70 | | | | | | | |
| P-2-78 | | | | 1.70 | | | | | | |
| P-2-82 | | | | | 1.70 | | | | | |
| P-2-84 | | | | | | 1.70 | | | | |
| P-2-85 | | | | | | | 1.70 | | | |
| P-2-91 | | | | | | | | 1.70 | | |
| P-2-96 | | | | | | | | | 1.70 | |
| P-2-99 | | | | | | | | | | 1.70 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-201 | P-202 | P-203 | P-204 | P-205 | P-206 | P-207 | P-208 | P-209 | P-210 |
| Black | 10 | 10 | 10 | 10 | 10 | 10 | 10 | 10 | 10 | 10 |
| colorant | | | | | | | | | | |
| P-1-27 | 23.55 | 23.55 | 23.55 | 23.55 | 23.55 | 23.55 | 23.55 | 23.55 | 23.55 | 23.55 |
| P-2-3 | 1.70 | | | | | | | | | |
| P-2-8 | | 1.70 | | | | | | | | |
| P-2-12 | | | 1.70 | | | | | | | |
| P-2-13 | | | | 1.70 | | | | | | |
| P-2-18 | | | | | 1.70 | | | | | |
| P-2-23 | | | | | | 1.70 | | | | |
| P-2-27 | | | | | | | 1.70 | | | |
| P-2-30 | | | | | | | | 1.70 | | |
| P-2-33 | | | | | | | | | 1.70 | |
| P-2-36 | | | | | | | | | | 1.70 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-211 | P-212 | P-213 | P-214 | P-215 | P-216 | P-217 | P-218 | P-219 | P-220 |
| Black | 10 | 10 | 10 | 10 | 10 | 10 | 10 | 10 | 10 | 10 |
| colorant | | | | | | | | | | |
| P-1-27 | 23.25 | 23.25 | 23.25 | 23.25 | 23.25 | 23.25 | 23.25 | 23.25 | 23.25 | 23.25 |
| P-2-41 | 2 | | | | | | | | | |
| P-2-42 | | 2 | | | | | | | | |
| P-2-49 | | | 2 | | | | | | | |
| P-2-54 | | | | 2 | | | | | | |
| P-2-59 | | | | | 2 | | | | | |
| P-2-64 | | | | | | 2 | | | | |
| P-2-69 | | | | | | | 2 | | | |
| P-2-74 | | | | | | | | 2 | | |
| P-2-78 | | | | | | | | | 2 | |
| P-2-82 | | | | | | | | | | 2 |
| Epoxy- | 22.10 | 22.10 | 22.10 | 22.10 | 22.10 | 22.10 | 22.10 | 22.10 | 22.10 | 22.10 |
| based | | | | | | | | | | |
| additive | | | | | | | | | | |
| TTA- | | | | | | | | | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 20.65 | 20.65 | 20.65 | 20.65 |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | 6 | 6 |
| TPO | | | | | | | | | | |
| Initiator | 16 | 16 | 16 | 16 | 16 | 16 | 16 | 16 | 16 | 16 |
| NIT | | | | | | | | | | |
| | P-221 | P-222 | P-223 | P-224 | P-225 | P-226 | P-227 | P-228 | | |
| Black | 10 | 10 | 10 | 10 | 10 | 10 | 10 | 10 | | |
| colorant | | | | | | | | | | |
| P-1-18 | | | | | | 25.25 | | | | |
| P-1-27 | 23.25 | 23.25 | 23.25 | 23.25 | 23.25 | | | | | |
| P-2-18 | | | | | | | 0.5 | | | |
| P-2-84 | 2 | | | | | | | | | |
| P-2-85 | | 2 | | | | | | | | |
| P-2-91 | | | 2 | | | | | | | |
| P-2-96 | | | | 2 | | | | | | |
| P-2-99 | | | | | 2 | | | | | |
| Epoxy- | | | | | | | | | | |
| based | | | | | | | | | | |
| additive | | | | | | | | | | |
| TTA- | 22.10 | 22.10 | 22.10 | 22.10 | 22.10 | 22.10 | 22.10 | 22.10 | | |
| 101 | | | | | | | | | | |
| (Tetra | | | | | | | | | | |
| chem | | | | | | | | | | |
| Corp.) | | | | | | | | | | |
| Epoxy- | 20.65 | 20.65 | 20.65 | 20.65 | 20.65 | 20.65 | 45.40 | 45.90 | | |
| based | | | | | | | | | | |
| additive | | | | | | | | | | |
| TTA- | | | | | | | | | | |
| 236 | | | | | | | | | | |
| (Tetra | | | | | | | | | | |
| chem | | | | | | | | | | |
| Corp.) | | | | | | | | | | |
| Initiator | 6 | 6 | 6 | 6 | 6 | 6 | 6 | 6 | | |
| TPO | | | | | | | | | | |

| | | | | | | | | |
|---|---|---|---|---|---|---|---|---|
| Initiator | 16 | 16 | 16 | 16 | 16 | 16 | 16 | 16 |
| NIT | | | | | | | | |

### 3. Preparation of Protective Layer

### 1) Substrate Preparation Step

A 100×100 mm bare glass substrate was prepared, and cleaning of the substrate was performed by performing UV ozone treatment and plasma treatment.

### 2) Protective Layer Composition Coating Step

The compositions P-1 to P-228 prepared in Table 1 were supplied to a KM 1024 inkjet printer head from KONICA MINOLTA, and the protective layer composition was discharged to form a coating layer such that a film coating thickness was 1 to 100 μm.

### 3) Exposure Step

The coating layer applied to the substrate was subjected to a UV curing process using a UV-LED light lamp from Phoseon Technology at a wavelength of 250 to 400 nm under conditions of a distance between the lamp and the coating layer of about 10 cm and an integrated light amount of about 3 J/cm² to prepare the protective layer.

### 4. Evaluation of Substrate Adhesion of Protective Layer

Adhesion of the protective layer prepared in the above-described protective layer preparation process was measured through cross-cut evaluation in accordance with the ASTM D3359 standard. A crosshatch pattern was made on the coating film surface at 1.5 mm intervals in both horizontal and vertical directions using an 11-blade cutter, and then an adhesive tape was attached to the grid surface and peeled off. The degree of peeling of the coating surface was measured and evaluated according to the following criteria, and the results are summarized in Table 2.

### <Cross-Cut Evaluation Criteria (ASTM D3359)>

5B: Peeled cross-cut area of 0%
4B: Peeled cross-cut area within 5%
3B: Peeled cross-cut area within 5 to 15%
2B: Peeled cross-cut area within 15 to 35%
1B: Peeled cross-cut area within 35 to 65%
0B: Peeled cross-cut area of 65% or more

TABLE 2

| | Composition | Adhesion |
|---|---|---|
| Comparative | P-226 | 3B |
| Example 1 | | |
| Comparative | P-227 | 0B |
| Example 2 | | |
| Comparative | P-228 | 0B |
| Example 3 | | |
| Example 1 | P-1 | 5B |
| Example 2 | P-2 | 5B |
| Example 3 | P-3 | 5B |
| Example 4 | P-4 | 5B |
| Example 5 | P-5 | 5B |
| Example 6 | P-6 | 5B |
| Example 7 | P-7 | 5B |
| Example 8 | P-8 | 5B |
| Example 9 | P-9 | 5B |
| Example 10 | P-10 | 5B |
| Example 11 | P-11 | 5B |
| Example 12 | P-12 | 5B |
| Example 13 | P-13 | 5B |
| Example 14 | P-14 | 5B |
| Example 15 | P-15 | 5B |
| Example 16 | P-16 | 5B |
| Example 17 | P-17 | 5B |
| Example 18 | P-18 | 5B |
| Example 19 | P-19 | 5B |
| Example 20 | P-20 | 5B |
| Example 21 | P-21 | 5B |
| Example 22 | P-22 | 5B |
| Example 23 | P-23 | 5B |
| Example 24 | P-24 | 5B |
| Example 25 | P-25 | 5B |
| Example 26 | P-26 | 5B |
| Example 27 | P-27 | 5B |
| Example 28 | P-28 | 5B |
| Example 29 | P-29 | 5B |
| Example 30 | P-30 | 5B |
| Example 31 | P-31 | 5B |
| Example 32 | P-32 | 5B |
| Example 33 | P-33 | 5B |
| Example 34 | P-34 | 5B |
| Example 35 | P-35 | 5B |
| Example 36 | P-36 | 5B |
| Example 37 | P-37 | 5B |
| Example 38 | P-38 | 5B |
| Example 39 | P-39 | 5B |
| Example 40 | P-40 | 5B |
| Example 41 | P-41 | 5B |
| Example 42 | P-42 | 5B |
| Example 43 | P-43 | 5B |
| Example 44 | P-44 | 5B |
| Example 45 | P-45 | 5B |
| Example 46 | P-46 | 5B |
| Example 47 | P-47 | 5B |
| Example 48 | P-48 | 5B |
| Example 49 | P-49 | 5B |
| Example 50 | P-50 | 5B |
| Example 51 | P-51 | 5B |
| Example 52 | P-52 | 5B |
| Example 53 | P-53 | 5B |
| Example 54 | P-54 | 5B |
| Example 55 | P-55 | 5B |
| Example 56 | P-56 | 5B |
| Example 57 | P-57 | 5B |
| Example 58 | P-58 | 5B |
| Example 59 | P-59 | 5B |
| Example 60 | P-60 | 5B |
| Example 61 | P-61 | 5B |
| Example 62 | P-62 | 5B |
| Example 63 | P-63 | 5B |
| Example 64 | P-64 | 5B |
| Example 65 | P-65 | 5B |
| Example 66 | P-66 | 5B |
| Example 67 | P-67 | 5B |
| Example 68 | P-68 | 5B |
| Example 69 | P-69 | 5B |
| Example 70 | P-70 | 5B |
| Example 71 | P-71 | 5B |
| Example 72 | P-72 | 5B |
| Example 73 | P-73 | 5B |
| Example 74 | P-74 | 5B |
| Example 75 | P-75 | 5B |
| Example 76 | P-76 | 5B |
| Example 77 | P-77 | 5B |
| Example 78 | P-78 | 5B |
| Example 79 | P-79 | 5B |
| Example 80 | P-80 | 5B |
| Example 81 | P-81 | 5B |
| Example 82 | P-82 | 5B |
| Example 83 | P-83 | 5B |
| Example 84 | P-84 | 5B |
| Example 85 | P-85 | 5B |
| Example 86 | P-86 | 5B |
| Example 87 | P-87 | 5B |
| Example 88 | P-88 | 5B |
| Example 89 | P-89 | 5B |
| Example 90 | P-90 | 5B |
| Example 91 | P-91 | 5B |
| Example 92 | P-92 | 5B |
| Example 93 | P-93 | 5B |
| Example 94 | P-94 | 5B |
| Example 95 | P-95 | 5B |
| Example 96 | P-96 | 5B |
| Example 97 | P-97 | 5B |
| Example 98 | P-98 | 5B |
| Example 99 | P-99 | 5B |
| Example 100 | P-100 | 5B |
| Example 101 | P-101 | 5B |
| Example 102 | P-102 | 5B |
| Example 103 | P-103 | 5B |
| Example 104 | P-104 | 5B |
| Example 105 | P-105 | 5B |
| Example 106 | P-106 | 5B |
| Example 107 | P-107 | 5B |
| Example 108 | P-108 | 5B |
| Example 109 | P-109 | 5B |
| Example 110 | P-110 | 5B |
| Example 111 | P-111 | 5B |
| Example 112 | P-112 | 5B |
| Example 113 | P-113 | 5B |
| Example 114 | P-114 | 5B |
| Example 115 | P-115 | 5B |
| Example 116 | P-116 | 5B |
| Example 117 | P-117 | 5B |
| Example 118 | P-118 | 5B |
| Example 119 | P-119 | 5B |
| Example 120 | P-120 | 5B |
| Example 121 | P-121 | 5B |
| Example 122 | P-122 | 5B |
| Example 123 | P-123 | 5B |
| Example 124 | P-124 | 5B |
| Example 125 | P-125 | 5B |
| Example 126 | P-126 | 5B |
| Example 127 | P-127 | 5B |
| Example 128 | P-128 | 5B |
| Example 129 | P-129 | 5B |
| Example 130 | P-130 | 5B |
| Example 131 | P-131 | 5B |
| Example 132 | P-132 | 5B |
| Example 133 | P-133 | 5B |
| Example 134 | P-134 | 5B |
| Example 135 | P-135 | 5B |
| Example 136 | P-136 | 5B |
| Example 137 | P-137 | 5B |
| Example 138 | P-138 | 5B |
| Example 139 | P-139 | 5B |
| Example 140 | P-140 | 5B |
| Example 141 | P-141 | 5B |
| Example 142 | P-142 | 5B |
| Example 143 | P-143 | 5B |
| Example 144 | P-144 | 5B |
| Example 145 | P-145 | 5B |
| Example 146 | P-146 | 5B |
| Example 147 | P-147 | 5B |
| Example 148 | P-148 | 5B |
| Example 149 | P-149 | 5B |
| Example 150 | P-150 | 5B |
| Example 151 | P-151 | 5B |
| Example 152 | P-152 | 5B |
| Example 153 | P-153 | 5B |
| Example 154 | P-154 | 5B |
| Example 155 | P-155 | 5B |
| Example 156 | P-156 | 5B |
| Example 157 | P-157 | 5B |
| Example 158 | P-158 | 5B |
| Example 159 | P-159 | 5B |
| Example 160 | P-160 | 5B |
| Example 161 | P-161 | 5B |
| Example 162 | P-162 | 5B |
| Example 163 | P-163 | 5B |
| Example 164 | P-164 | 5B |
| Example 165 | P-165 | 5B |
| Example 166 | P-166 | 5B |
| Example 167 | P-167 | 5B |
| Example 168 | P-168 | 5B |
| Example 169 | P-169 | 5B |
| Example 170 | P-170 | 5B |
| Example 171 | P-171 | 5B |
| Example 172 | P-172 | 5B |
| Example 173 | P-173 | 5B |
| Example 174 | P-174 | 5B |
| Example 175 | P-175 | 5B |
| Example 176 | P-176 | 5B |
| Example 177 | P-177 | 5B |
| Example 178 | P-178 | 5B |
| Example 179 | P-179 | 5B |
| Example 180 | P-180 | 5B |
| Example 181 | P-181 | 5B |
| Example 182 | P-182 | 5B |
| Example 183 | P-183 | 5B |
| Example 184 | P-184 | 5B |
| Example 185 | P-185 | 5B |
| Example 186 | P-186 | 5B |
| Example 187 | P-187 | 5B |
| Example 188 | P-188 | 5B |
| Example 189 | P-189 | 5B |
| Example 190 | P-190 | 5B |
| Example 191 | P-191 | 5B |
| Example 192 | P-192 | 5B |
| Example 193 | P-193 | 5B |
| Example 194 | P-194 | 5B |
| Example 195 | P-195 | 5B |
| Example 196 | P-196 | 5B |
| Example 197 | P-197 | 5B |
| Example 198 | P-198 | 5B |
| Example 199 | P-199 | 5B |
| Example 200 | P-200 | 5B |
| Example 201 | P-201 | 5B |
| Example 202 | P-202 | 5B |
| Example 203 | P-203 | 5B |
| Example 204 | P-204 | 5B |
| Example 205 | P-205 | 5B |
| Example 206 | P-206 | 5B |
| Example 207 | P-207 | 5B |
| Example 208 | P-208 | 5B |
| Example 209 | P-209 | 5B |
| Example 210 | P-210 | 5B |
| Example 211 | P-211 | 5B |
| Example 212 | P-212 | 5B |
| Example 213 | P-213 | 5B |
| Example 214 | P-214 | 5B |
| Example 215 | P-215 | 5B |
| Example 216 | P-216 | 5B |
| Example 217 | P-217 | 5B |
| Example 218 | P-218 | 5B |
| Example 219 | P-219 | 5B |
| Example 220 | P-220 | 5B |
| Example 221 | P-221 | 5B |
| Example 222 | P-222 | 5B |
| Example 223 | P-223 | 5B |
| Example 224 | P-224 | 5B |
| Example 225 | P-225 | 5B |

In Table 2, it can be confirmed that the adhesion of the Examples is excellent as 5B compared to the Comparative Examples. This may be a result of a polymer material composed of an acrylate monomer forming hydrogen bonds with an organic interface through a flexible chain structure, while a Si adhesion promoter can create covalent bonds with the substrate surface, and when these two components are present together, long-chain molecules of the acrylate penetrate between siloxane (Si—O) networks to form a three-dimensional composite structure, thereby exerting a mechanical complementary effect.

On the other hand, in the case of Comparative Example 1 in which the adhesion promoter is absent, only van der Waals forces act between the substrate and the composition, which may be a result of the adhesion being reduced due to relatively weak bonding strength.

In addition, in the case of Comparative Example 2 in which the acrylate-based monomer is absent, only strong covalent bonds between the substrate and silicon remain, which may be a result of the adhesion being lowered by causing brittle fracture.

In addition, in the case of Comparative Example 3 in which the acrylate-based monomer and the adhesion promoter are absent, the composition relies only on physical adsorption with the substrate, which may be a result of the adhesion being very low.

The present disclosure is not limited to the embodiments and may be manufactured in various different forms.

The above description is merely an illustrative explanation of the present disclosure, and those skilled in the art to which the present disclosure pertains will be able to make various modifications without departing from the essential characteristics of the present disclosure.

Therefore, the embodiments disclosed in the present disclosure are for illustrative purposes rather than limiting the present disclosure, and the spirit and scope of the present disclosure are not limited by these embodiments. The scope of protection of the present disclosure should be interpreted by the claims, and all technologies within the equivalent scope thereof should be interpreted as being included in the scope of rights of the present disclosure.

What is claimed is:

1. A protective layer composition comprising: a colorant; a monomer comprising an acrylate group; and an adhesion promoter comprising silicon (Si).

2. The protective layer composition of claim 1, wherein the monomer is a compound represented by Formula 1 below: 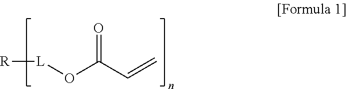
wherein in Formula 1,
R is selected from the group consisting of hydrogen; deuterium; a C₁-C₃₀ alkyl group; a C₂-C₃₀ alkenyl group; a C₂-C₃₀ alkynyl group; a C₃-C₃₀ cycloalkyl group; a C₁-C₃₀ ether group; a C₁-C₃₀ ketone group; a C₁-C₃₀ ester group; a C₁-C₃₀ alkoxy group; a C₆-C₃₀ aryl group; a C₂-C₃₀ heterocyclic group comprising at least one heteroatom selected from the group consisting of oxygen (O), nitrogen (N), sulfur(S), silicon (Si), and phosphorus (P); a C₆-C₃₀ aryloxy group; a hydroxy group; and combinations thereof,
L is selected from the group consisting of a single bond; a C₁-C₃₀ alkylene group; a C₂-C₃₀ alkenylene group; a C₂-C₃₀ alkynylene group; a C₃-C₃₀ cycloalkylene group; a C₁-C₃₀ ether group; a C₁-C₃₀ ketone group; a C₁-C₃₀ ester group; a C₁-C₃₀ alkoxylene group; a C₆-C₃₀ arylene group; a C₂-C₃₀ heterocyclic group comprising at least one heteroatom selected from the group consisting of O, N, S, Si, and P; a C₆-C₃₀ aryloxy group; and combinations thereof,
in R and L of Formula 1,
the C₁-C₃₀ alkyl group; the C₂-C₃₀ alkenyl group; the C₂-C₃₀ alkynyl group; the C₃-C₃₀ cycloalkyl group; the C₁-C₃₀ ether group; the C₁-C₃₀ ketone group; the C₁-C₃₀ ester group; the C₁-C₃₀ alkoxy group; the C₆-C₃₀ aryl group; the C₂-C₃₀ heterocyclic group comprising at least one heteroatom selected from the group consisting of O, N, S, Si, and P; and the C₆-C₃₀ aryloxy group may each independently be further substituted with one or more substituents selected from the group consisting of deuterium, a halogen group, a hydroxy group, a nitrile group, a nitro group, a carbonyl group, an ether group, an ester group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P,
and n is an integer from 1 to 4.

3. The protective layer composition of claim 1, wherein the monomer is at least one of compounds represented by Formulas P-1-1 to P-1-36 below:

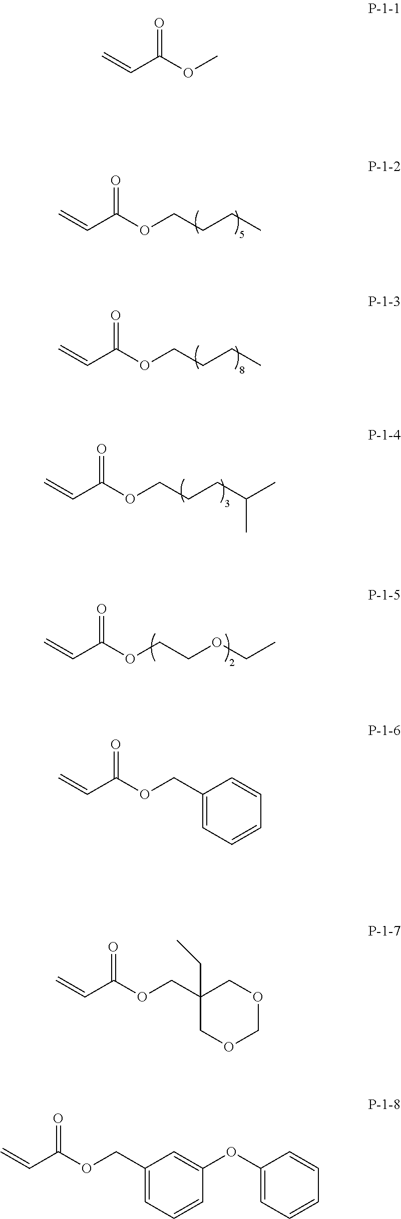

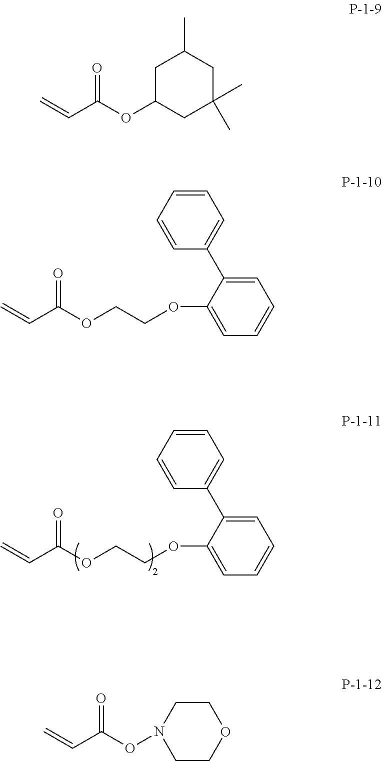

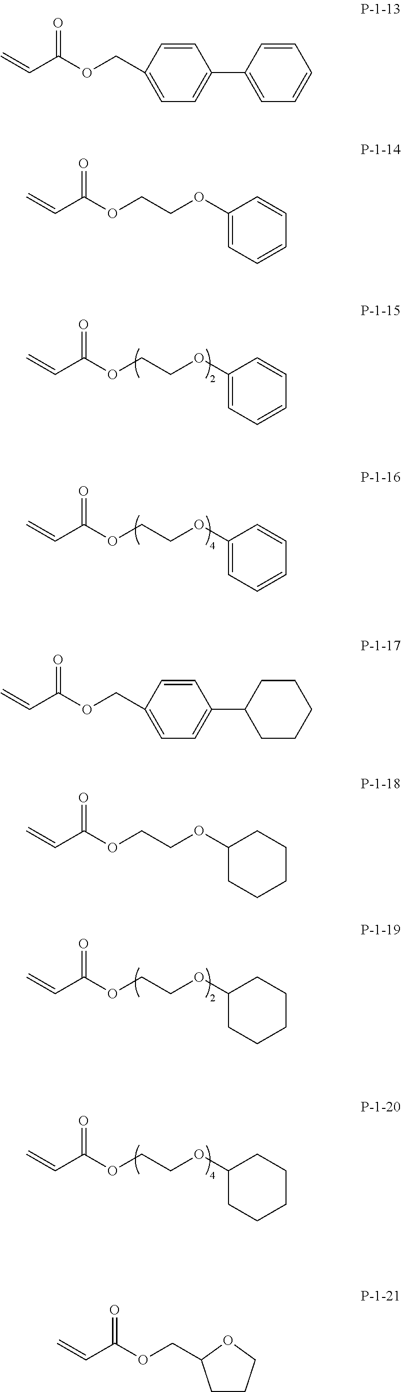

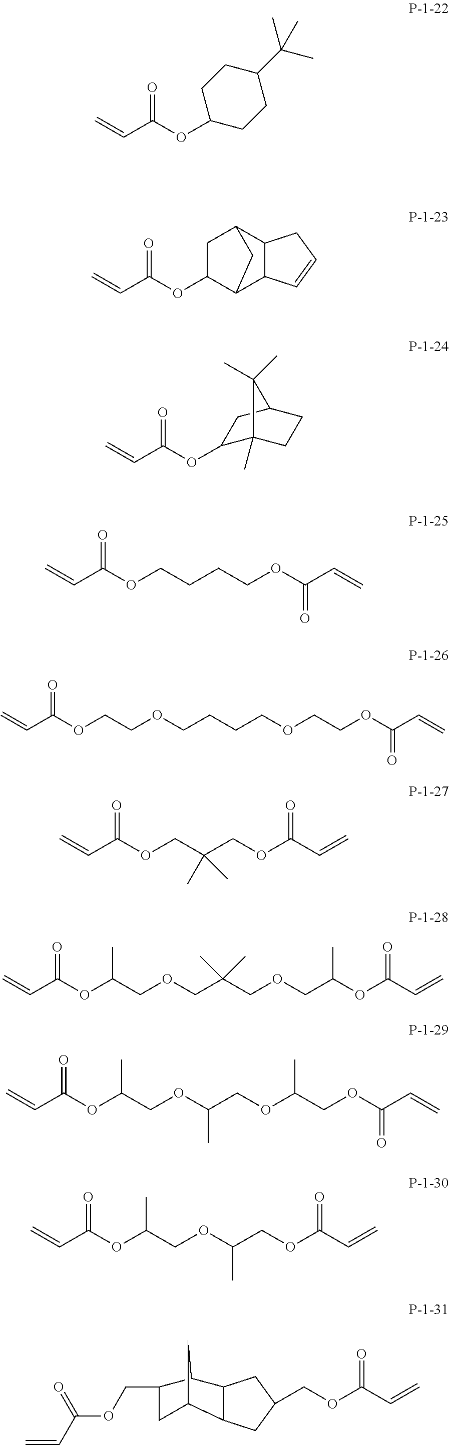

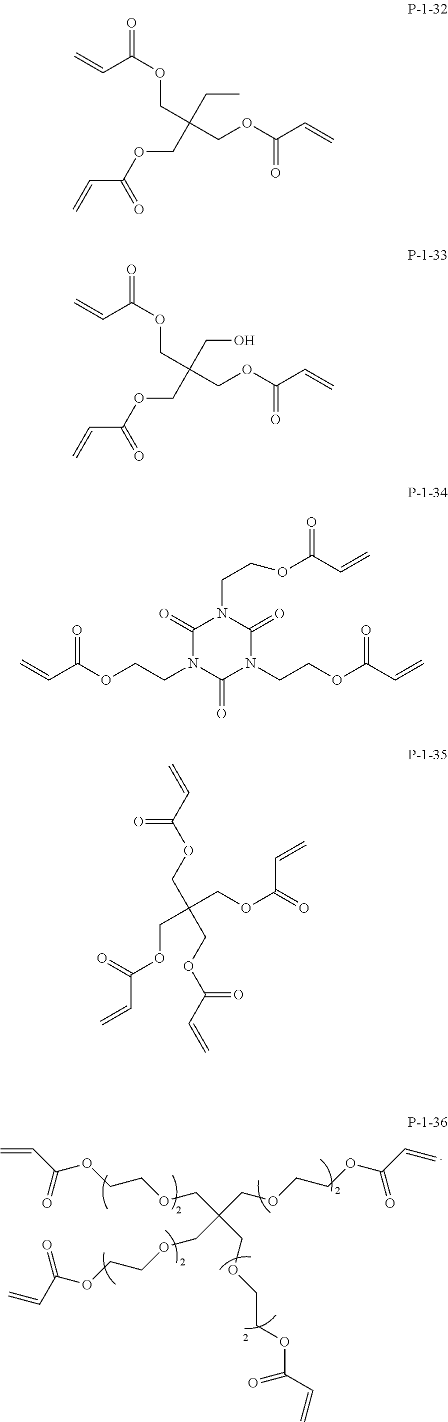

4. The protective layer composition of claim 1, wherein the adhesion promoter is represented by Formula 2 below: 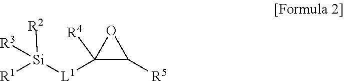
wherein in Formula 2,
R¹ to R⁵ are each independently selected from the group consisting of hydrogen; deuterium; a C₁-C₃₀ alkyl group; a C₂-C₃₀ alkenyl group; a C₂-C₃₀ alkynyl group; a C₃-C₃₀ cycloalkyl group; a C₁-C₃₀ ether group; a C₁-C₃₀ ketone group; a C₁-C₃₀ ester group; a C₁-C₃₀ alkoxy group; a C₆-C₃₀ aryl group; a C₂-C₃₀ heterocyclic group comprising at least one heteroatom selected from the group consisting of oxygen (O), nitrogen (N), sulfur(S), silicon (Si), and phosphorus (P); a C₆-C₃₀ aryloxy group; and combinations thereof,
L¹ is selected from the group consisting of a C₁-C₃₀ alkylene group; a C₂-C₃₀ alkenylene group; a C₂-C₃₀ alkynylene group; a C₃-C₃₀ cycloalkylene group; a C₁-C₃₀ ether group; a C₁-C₃₀ ketone group; a C₁-C₃₀ ester group; a C₁-C₃₀ alkoxylene group; a C₆-C₃₀ arylene group; a C₂-C₃₀ heterocyclic group comprising at least one heteroatom selected from the group consisting of O, N, S, Si, and P; a C₆-C₃₀ aryloxy group; and combinations thereof,
atoms constituting L¹ and R⁵ may be bonded to each other to form a ring,
in R¹ to R⁵ and L¹ of Formula 2,
the C₁-C₃₀ alkyl group; the C₂-C₃₀ alkenyl group; the C₂-C₃₀ alkynyl group; the C₃-C₃₀ cycloalkyl group; the C₁-C₃₀ ether group; the C₁-C₃₀ ketone group; the C₁-C₃₀ ester group; the C₁-C₃₀ alkoxy group; the C₆-C₃₀ aryl group; the C₂-C₃₀ heterocyclic group comprising at least one heteroatom selected from the group consisting of O, N, S, Si, and P; and the C₈-C₃₀ aryloxy group may each independently be further substituted with one or more substituents selected from the group consisting of deuterium, a halogen group, a hydroxy group, a nitrile group, a nitro group, a carbonyl group, an ether group, an ester group, a C₁-C₃₀ alkyl group, a C₁-C₃₀ alkoxy group, a C₁-C₃₀ alkylamine group, a C₁-C₃₀ alkylsilyl group, a C₁-C₃₀ alkylthiophene group, a C₂-C₃₀ alkenyl group, a C₂-C₃₀ alkynyl group, a C₃-C₃₀ cycloalkyl group, a C₆-C₃₀ aryl group, a C₆-C₃₀ aryloxy group, a C₆-C₃₀ arylamine group, a C₆-C₃₀ arylsilyl group, a C₆-C₃₀ arylthiophene group, a C₆-C₃₀ aryl group substituted with deuterium, a C₇-C₃₀ arylalkyl group, a C₈-C₃₀ arylalkenyl group, a silane group, a siloxane group, a boron group, a thiol group, a germanium group, and a C₂-C₃₀ heterocyclic group comprising at least one heteroatom selected from the group consisting of O, N, S, Si, and P.

5. The protective layer composition of claim 1, wherein the adhesion promoter is at least one of compounds represented by Formulas P-2-1 to P-2-99 below:

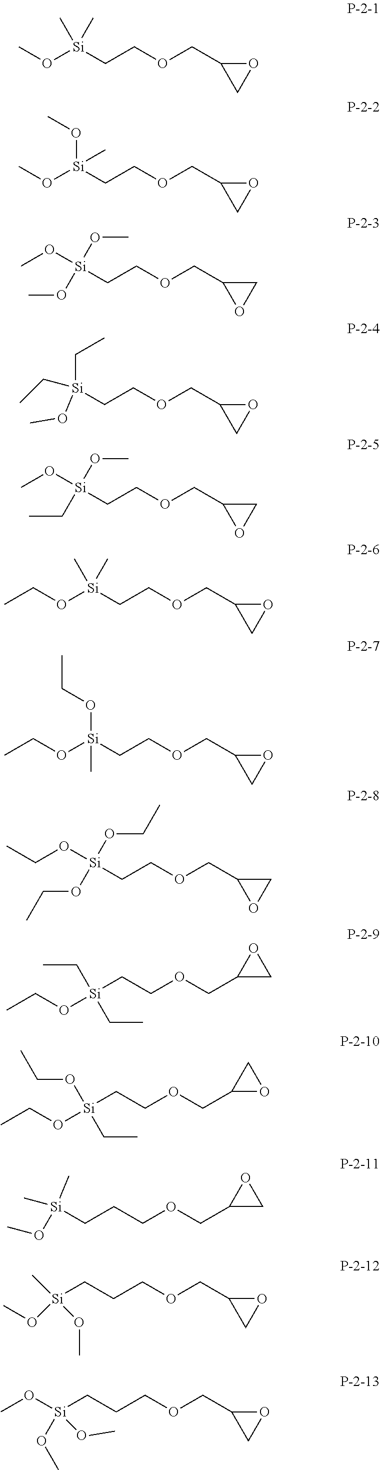

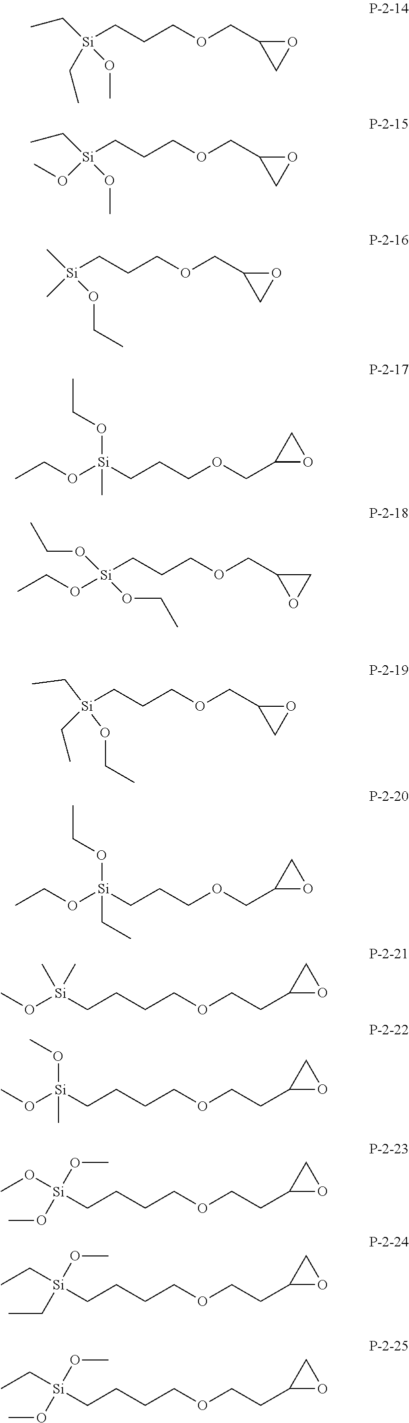

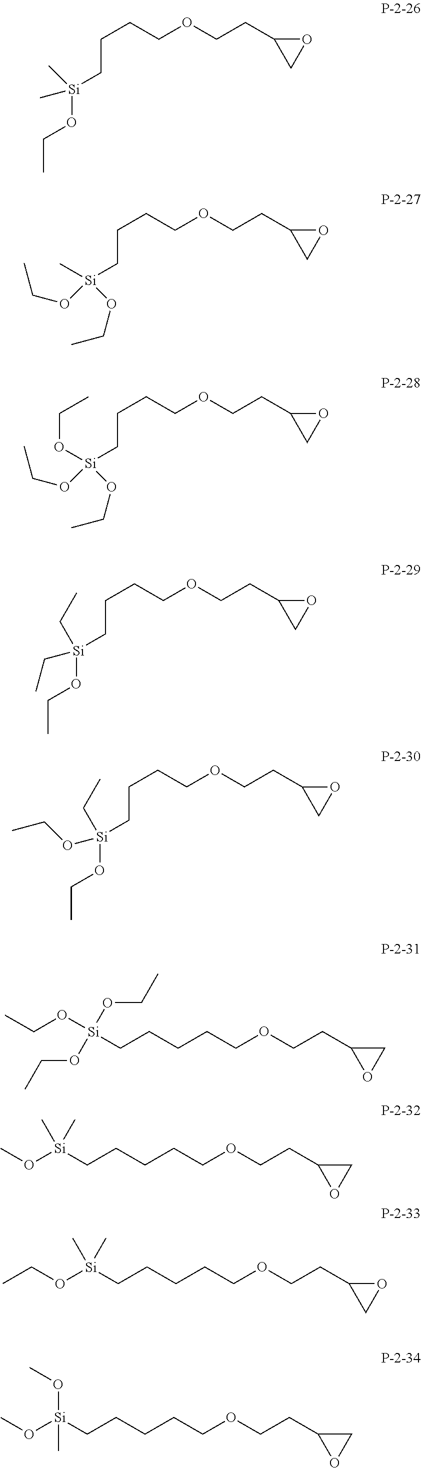

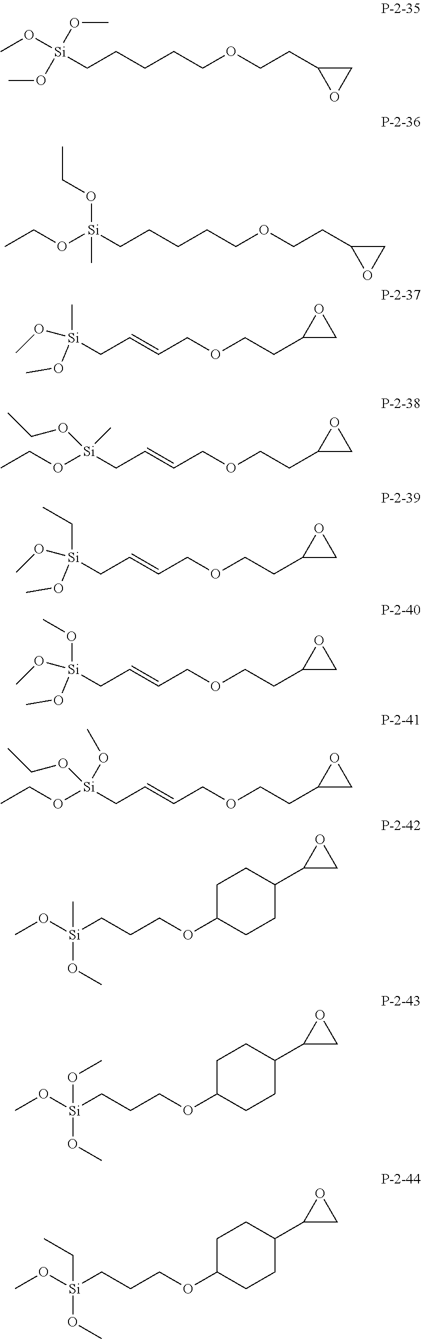

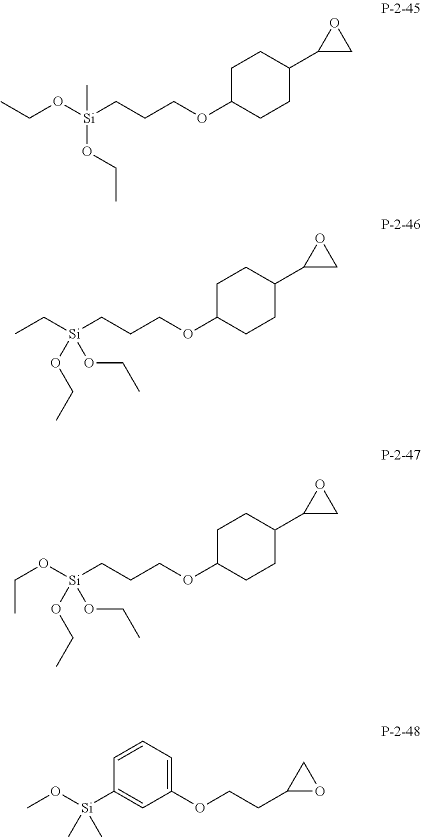 [SMILES: CCO[Si](C)(CCCOC1CCC(C2CO2)CC1)OCC ; CCO[Si](CC)(CCCOC1CCC(C2CO2)CC1)OCC ; CCO[Si](CCCOC1CCC(C2CO2)CC1)(OCC)OCC ; CO[Si](C)(C)c1cccc(OCCC2CO2)c1]

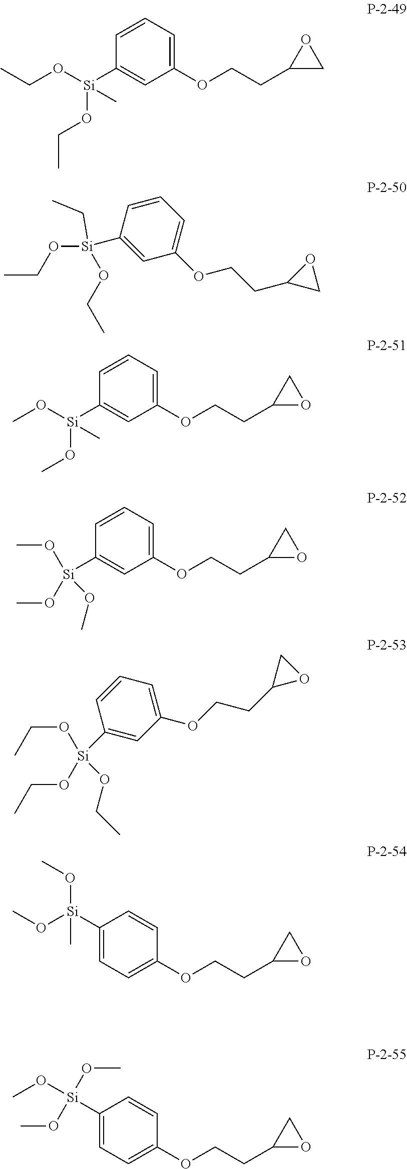

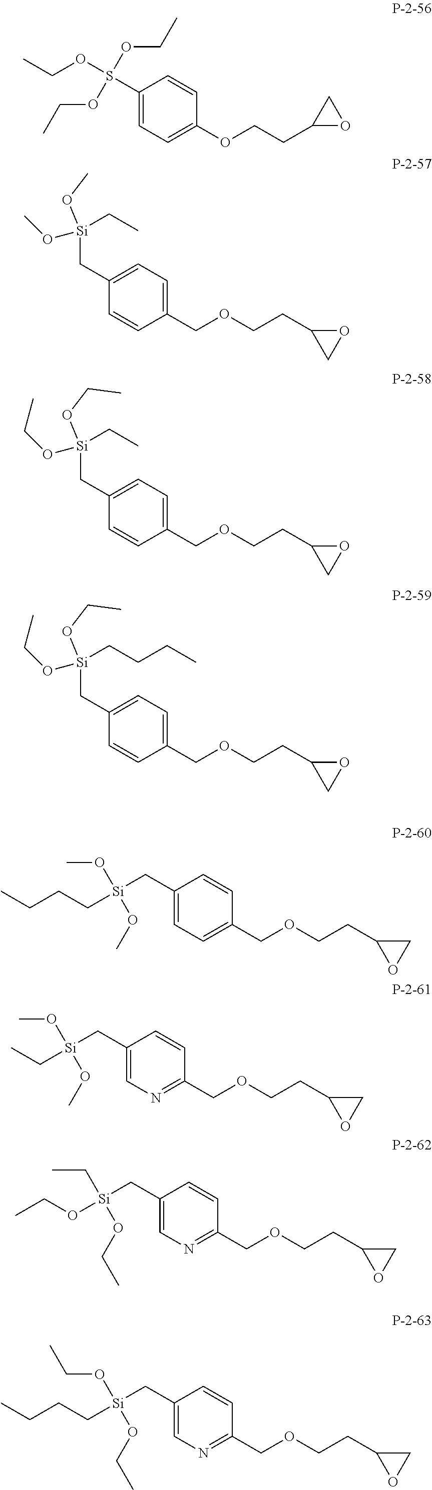

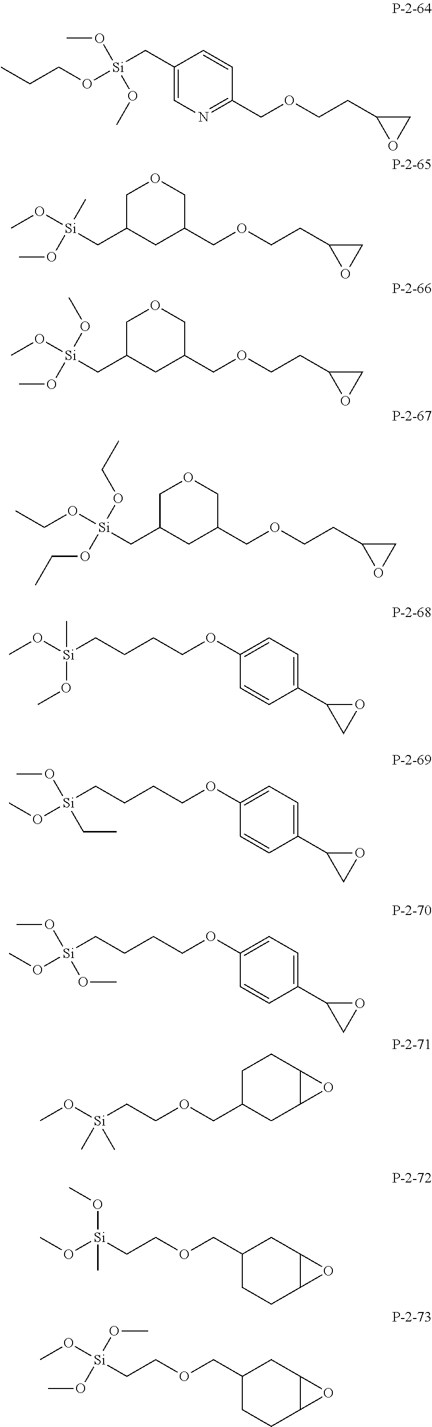

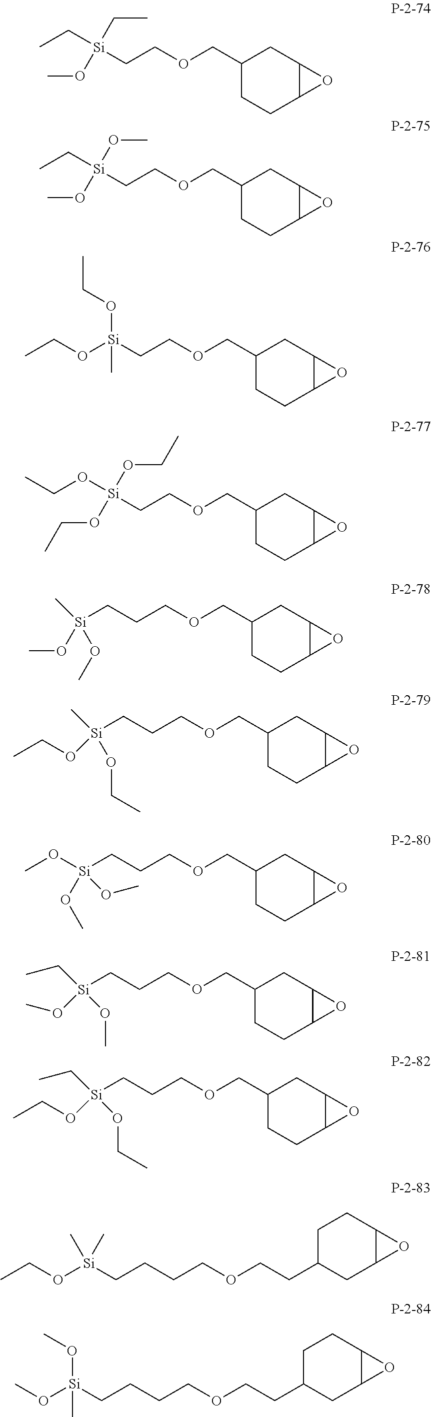

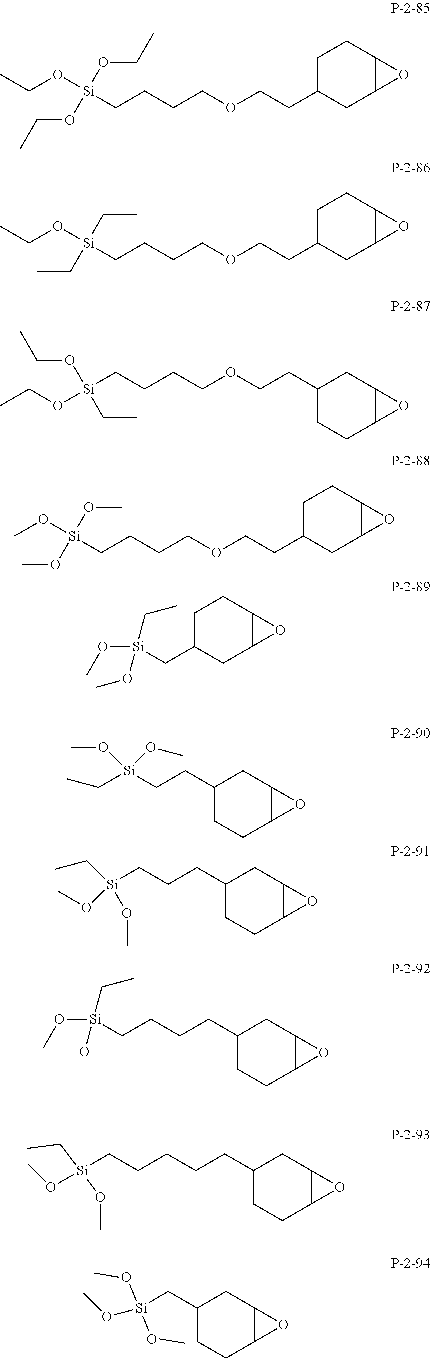

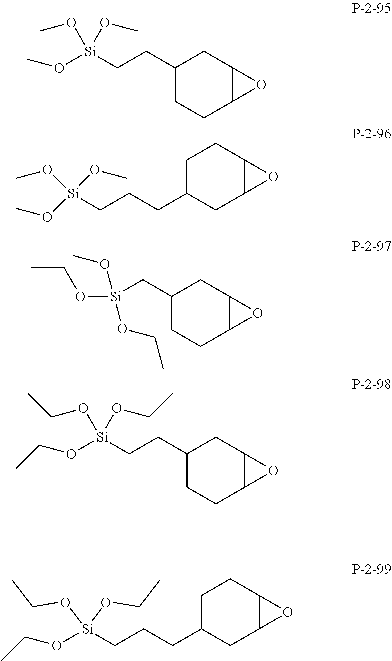

6. The protective layer composition of claim 1, wherein the colorant comprises a black pigment.

7. The protective layer composition of claim 1, further comprising an initiator.

8. The protective layer composition of claim 7, wherein the initiator is a radical initiator.

9. A protective layer comprising the protective layer composition of claim 1.

10. A display device comprising:
a substrate;
a pixel array layer disposed on the substrate; and
a protective layer disposed under the substrate, the protective layer comprising the protective layer composition of claim 1.

11. The display device of claim 10, wherein the protective layer is disposed to contact the substrate.
